(19) United States
(12) Patent Application Publication
(10) Pub. No.: US 2026/0062833 A1
(43) Pub. Date: Mar. 5, 2026

(54) Silicon Carbide Vapor Source Material for use in a Sublimation System for Growing Crystalline Silicon Carbide

(71) Applicant: Wolfspeed, Inc., Durham, NC (US)

(72) Inventors: Valeri Fedorovich Tsvetkov, Durham, NC (US); William Henry Brixius, Hillsborough, NC (US); Steven Herbert Griffiths, Morrisville, NC (US); Brian Bennett Haidet, Raleigh, NC (US); Elif Balkas, Cary, NC (US); Caleb Andrew Kent, Durham, NC (US); Yuri I. Khlebnikov, Raleigh, NC (US)

(21) Appl. No.: 18/963,117

(22) Filed: Nov. 27, 2024

Related U.S. Application Data
(60) Provisional application No. 63/689,291, filed on Aug. 30, 2024.

(51) Int. Cl. C30B 23/02; C30B 29/36

(52) U.S. Cl. CPC C30B 23/02; C30B 29/36

(57) ABSTRACT

A silicon carbide source material structure for use in a sublimation system for growing single crystal silicon carbide is provided. The silicon carbide source material structure may comprise a first layer and a second layer, the first layer being different from the second layer in at least one property.

### PRIORITY CLAIM

The present application claims the benefit of priority of U.S. Provisional Application Ser. No. 63/689,291, filed on Aug. 30, 2024, which is incorporated herein by reference.

### FIELD

The present disclosure relates generally to semiconductor workpieces and semiconductor workpiece fabrication.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices.

Power semiconductor devices may be packaged into various semiconductor device packages, such as discrete semiconductor device packages and power modules. Power modules may include one or more power devices and other circuit components and can be used, for instance, to dynamically switch large amounts of power through various components, such as motors, inverters, generators, and the like.

Semiconductor devices may be fabricated from wide bandgap semiconductor materials, such as silicon carbide and/or Group III nitride-based semiconductor materials. The fabrication process for power semiconductor devices may require processing of wide bandgap semiconductor wafers, such as silicon carbide semiconductor wafers.

Single crystal silicon carbide (SiC) has proven to be a very useful wafer material in the manufacture of such semiconductor devices. Due to its physical strength and excellent resistance to many chemicals, SiC may be used to fabricate very robust substrates adapted for use in the semiconductor industry. SiC has excellent electrical properties, including radiation hardness, high breakdown field, a relatively wide band gap, high saturated electron drift velocity, high-temperature operation, and absorption and emission of high-energy photons in the blue, violet, and ultraviolet regions of the optical spectrum.

SiC crystalline material may be produced using various seeded sublimation growth processes. In a typical SiC growth process, a seed material and source material are arranged in a reaction crucible which is then heated to the sublimation temperature of the source material. By controlled heating of the environment surrounding the reaction crucible, a thermal gradient is developed between the sublimating source material and the marginally cooler seed material. By means of the thermal gradient, source material in a vapor phase is transported onto the seed material where it condenses to grow a bulk crystalline boule. This type of crystalline growth process is commonly referred to as physical vapor transport (PVT) process.

A resulting SiC boule may then be sliced using into wafers, and the individual wafers may then be used as seed material for a seeded sublimation growth process, or as substrates upon which a variety of semiconductor devices (e.g., power semiconductor devices and optical applications, such as LEDs, windows, photo-diodes, etc.) may be formed.

### SUMMARY

Aspects and advantages of embodiments of the present disclosure will be set forth in part in the following description, or can be learned from the description, or can be learned through practice of the embodiments.

In one aspect, the present disclosure provides an example silicon carbide source material structure. In some implementations, the example silicon carbide source material structure includes a first layer and a second layer, the first layer being different from the second layer in at least one property.

In another aspect, the present disclosure provides an example silicon carbide source material structure for use in a sublimation system for growing single crystal silicon carbide. The silicon carbide source material structure includes silicon carbide and a dopant.

In another aspect, the present disclosure provides an example silicon carbide crystal growth sublimation system. The system includes a crucible, a silicon carbide source material structure, and a silicon carbide seed material. The source material comprises silicon carbide having a different polytype from the silicon carbide of the seed material.

In another aspect, the present disclosure provides an example method for growing a single crystal of silicon carbide. The method includes forming a silicon carbide source material structure, placing the silicon carbide source material structure in a reaction crucible, and heating the sublimation system to at least a sublimation temperature of the silicon carbide source material structure. Forming the silicon carbide source material structure comprises reacting a graphite preform having a needle coke structure with SiO gas.

In another aspect, the present disclosure provides an example silicon carbide crystal growth sublimation system including a crucible and the silicon carbide source material structure.

In another aspect, the present disclosure provides an example method for growing a single crystal of silicon carbide. The method includes placing the silicon carbide source material structure in a reaction crucible and heating the sublimation system to at least a sublimation temperature of the silicon carbide source material structure.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a sublimation system according to example embodiments of the present disclosure;

FIG. 2 depicts a sublimation system according to example embodiments of the present disclosure;

FIG. 3 depicts a sublimation system according to example embodiments of the present disclosure;

FIG. 4A depicts a silicon carbide source material structure according to example embodiments of the present disclosure;

FIG. 4B depicts a cross-sectional view of the silicon carbide source material structure shown in FIG. 4A;

FIG. 5 depicts a silicon carbide source material structure according to example embodiments of the present disclosure;

FIG. 6A depicts a cross-sectional view of a silicon carbide source material structure according to example embodiments of the present disclosure;

FIG. 6B depicts a cross-sectional view of a silicon carbide source material structure according to example embodiments of the present disclosure;

FIG. 6C depicts a top view of the silicon carbide source material structure shown in FIG. 6B;

FIG. 7A depicts a silicon carbide source material structure according to example embodiments of the present disclosure;

FIG. 7B depicts a silicon carbide source material structure according to example embodiments of the present disclosure;

FIG. 8A depicts a cross-sectional view of a silicon carbide source material structure according to example embodiments of the present disclosure;

FIG. 8B depicts a cross-sectional view of a silicon carbide source material structure according to example embodiments of the present disclosure;

FIG. 8C depicts a cross-sectional view of a silicon carbide source material structure according to example embodiments of the present disclosure;

FIG. 9 depicts a silicon carbide source material structure according to example embodiments of the present disclosure;

FIG. 10 depicts a silicon carbide source material powder according to example embodiments of the present disclosure;

FIG. 11 depicts a silicon carbide source material powder according to example embodiments of the present disclosure;

FIG. 12 depicts a silicon carbide source material powder according to example embodiments of the present disclosure;

FIG. 13A depicts a top view of a silicon carbide source material structure according to example embodiments of the present disclosure;

FIG. 13B depicts a perspective view of a silicon carbide source material structure according to example embodiments of the present disclosure;

FIG. 14 depicts a top view of a silicon carbide source material structure according to example embodiments of the present disclosure;

FIG. 15 depicts a top view of a silicon carbide source material structure according to example embodiments of the present disclosure;

FIG. 16 depicts a silicon carbide source material structure according to example embodiments of the present disclosure;

FIG. 17 depicts a powder bed fusion system that may be used according to example embodiments of the present disclosure;

FIG. 18 depicts a fused deposition modeling system according to example embodiments of the present disclosure;

FIG. 19 depicts a three-dimensional structure that may be formed from the composition according to example embodiments of the present disclosure;

FIGS. 20A-20C are cross-sectional views of FIG. 15 taken along a line 3A-3A, depicting a process for forming a three-dimensional structure according to example embodiments of the present disclosure;

FIG. 21 depicts a flow chart diagram of an example method according to example embodiments of the present disclosure;

FIG. 22 depicts a silicon carbide source material structure according to example embodiments of the present disclosure;

FIG. 23A depicts a source retention mechanism according to example embodiments of the present disclosure; and

FIG. 23B depicts a source retention mechanism according to example embodiments of the present disclosure.

FIGS. 24A-31 depict example crystal growth systems that include a baffle according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to systems and methods for growing crystalline silicon carbide (SiC), such as single crystal SiC. In some SiC growth processes, the reaction crucible is made of carbon (including, for example graphite and/or other carbon materials) and is heated using an inductive or resistive heating technique. The heating coils and associated insulation are carefully positioned in relation to the reaction crucible to establish and maintain the desired thermal gradient. Source material, such as powdered SiC, is commonly used in conjunction with vertically oriented or horizontally oriented reaction crucibles. The powdered SiC is retained in a lower portion of the reaction crucible and the seed material is positioned in an upper portion of the reaction crucible during the PVT process.

It would be advantageous to be able to better control the sublimation and SiC crystal growth properties. To achieve this, example embodiments of the present disclosure are directed to a silicon carbide source material structure, methods for making the silicon carbide source material structure, sublimation systems including the silicon carbide source material structure, and methods for growing a single crystal of silicon carbide using such systems.

In some embodiments, the silicon carbide source material structure may contain multiple layers varying in at least one property. For example, it may include an outer layer and an inner layer such that when used in a sublimation process, the outer layer sublimates first, followed by the inner layer. Varying the properties of the layers can affect the sublimation properties (e.g., rate, temperature required) and crystal growth properties (e.g., polytype, dopant concentration, defect concentration, shape, growth rate).

In some embodiments, the silicon carbide source material structure includes a dopant. The inclusion of a dopant in the source material provides a method for incorporating the dopant into the SiC single crystal. This is particularly useful for incorporating dopants which are not easily incorporated using a vapor source.

A system for growing a silicon carbide crystal via sublimation is also provided. The system may include, for example, a crucible, a silicon carbide source material structure, and a silicon carbide seed material. In some embodiments, the source material includes silicon carbide having a different polytype from the silicon carbide in the seed material.

A method for producing a silicon carbide source material structure is also provided. In one embodiment, for example, the method includes reacting a graphite preform having a needle coke structure with a silicon-containing gas (e.g., SiO, TEOS) and/or silicon containing vapor for graphite preform conversion.

In some embodiments, the structure may have a composite shape. As used herein, “composite shape” and “composite shaped” refer to any three-dimensional object or component that deviates from a cylindrical shape, or a composite structure containing multiple shaped solids which may have simple or complex shapes. Deviations from a cylindrical shape include forms with regular or irregular geometries that do not conform to the typical circular or elliptical cross-section of a cylinder. Such structures may exhibit various shapes, including but not limited to structures with polygonal cross-sections; irregularly curved structures; and shapes with holes, voids, surface variations, or combinations thereof. The term also includes shapes containing multiple interconnected or distinct substructures. The substructures may themselves be composite shaped or may be cylindrically shaped. The term encompasses a wide range of geometric configurations and excludes objects that maintain a uniform cylindrical profile throughout their entire volume.

As used herein, “shaped solid” and “solid structure” refer to non-powdered solid components. A non-powdered component, for example, can have a particle size of about 1 μm or greater, such as about 10 μm or greater, such as about 50 μm or greater, such as about 100 μm or greater, such as about 200 μm or greater, such as about 1000 μm or greater, such as about 1700 μm or greater, such as about 5 mm or greater, such as about 10 mm or greater. In some example embodiments, a shaped solid or solid structure may be formed by binding powdered particles together to form a composite material. Shaped solids may be shaped in an intentional manner to influence relevant properties, such as sublimation rate, vapor flow paths, thermal gradients, etc. As used herein, a powder or powdered material can refer to a particulate material having a particle size of about 10 mm or less, such as about 5 mm or less, such as about 2 mm or less, such as about 1 mm or less, such as about 500 μm or less, such as about 200 μm or less.

The use of a shaped solid silicon carbide source material structure can provide the sublimation system with various advantages to enhance crystal growth. For example, the shaped solid source material may have a greater density than a powdered source material, which allows the source material to take up less space in the reactor, leaving more space to grow the silicon carbide boule. For example, the density, porosity, and surface area of the source material may be controlled to provide faster sublimation of the silicon carbide. Further, the shaped solid source material may be designed to provide better control of thermal gradients, surface area, and flow paths within the source material. For example, a composite shaped structure may include complex geometry including shapes, features, symmetry, asymmetry, dimensions, thicknesses, and/or appendages to improve such parameters. As such, significant performance improvements can be achieved compared to using, for instance, powder bed source material.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, typical embodiments are described and, although specific terms are employed, they are used in a generic and descriptive sense only and not for purposes of limitation of the scope set forth in the following claims.

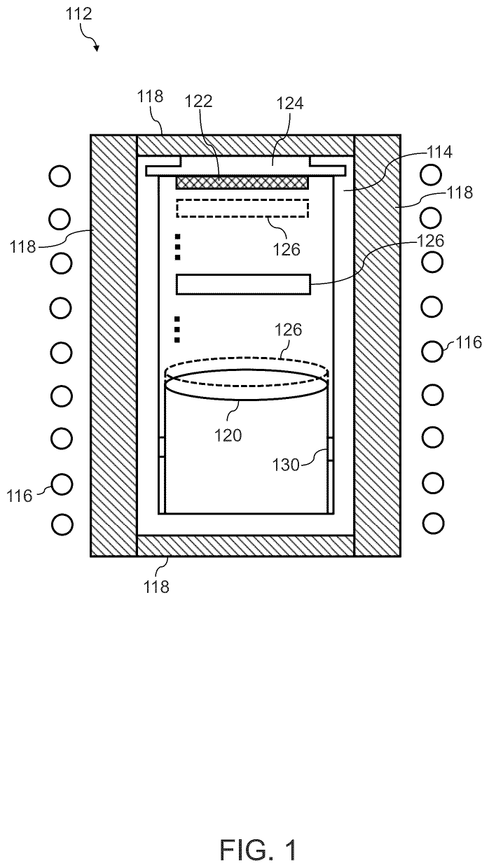

FIG. 1 is a cross sectional schematic diagram of a sublimation system 112 adapted for use in a seeded sublimation growth process of the type contemplated by certain embodiments of the disclosure. Sublimation system 112 includes a reaction crucible (also referred to as a susceptor or growth cell) 114 and a plurality of induction coils 116 adapted to heat reaction crucible 114 when electrical current is applied. Alternatively, a resistive heating approach may be applied to the heating of reaction crucible 114. Using any competent heating mechanism and approach, the temperature within a furnace housing sublimation system 112 may be controllable. The reaction crucible 114 may be made of graphite.

The furnace housing sublimation system 112 may also include one or more gas inlet and gas outlet ports and associated equipment allowing the controlled introduction and evacuation of gas from an environment surrounding reaction crucible 114. The introduction and evacuation of various gases to/from the environment surrounding reaction crucible 114 may be accomplished using a variety of inlets/outlets, pipes, valves, pumps, gas sources, and controllers. It will be further understood by those skilled in the art that sublimation system 102 may further incorporate in certain embodiments a water-cooled quartz vessel.

Reaction crucible 114 may be surrounded by insulation material 118. The composition, size, and placement of insulation material 118 will vary with individual sublimation systems 112 in order to define and/or maintain desired thermal gradients (both axially and radially) in relation to reaction crucible 114. For purposes of clarity, the term, “thermal gradient,” will be used herein to describe one or more thermal gradient(s) associated with reaction crucible 114. Those skilled in the art recognize that “the thermal gradient” established in embodiments of the disclosure will contain (or may be further characterized as having) axial and radial gradients, or may be characterized by a plurality of isotherms.

Prior to establishment of the thermal gradient, reaction crucible 114 is loaded with one or more source materials. As such, the reaction crucible includes one or more portions, as least one of which is capable of holding source material 120, which is represented by a generic cylinder for simplicity but, as further described herein, includes a silicon carbide structure as described herein. As illustrated in FIG. 1, source material 120 may be held in a lower portion of reaction crucible 114, as is common for one type of reaction crucible 114.

A seed material 122 may be placed above or in an upper portion of reaction crucible 114. Seed material 122 may take the form of a mono-crystalline SiC seed wafer having a diameter from about 50 to about 300 mm. A SiC single crystal boule will be grown from seed material 122 during the seeded sublimation growth process. The seed material 122 may have a 4H crystal structure, 6H crystal structure, or other crystal structure. The seed material 122 can be on-axis (e.g., end face parallel to the (0001) plane) or off-axis (e.g., end face non-parallel to the (0001) plane). Growth may occur on the silicon face or the carbon face of the seed material 122.

In some embodiments, the system may include a baffle 126. The baffle 126 may provide a mechanism for the transport of source vapor during sublimation of the source material 120. The baffle 126 may have any spatial orientation relative to the source material 120, the seed crystal 122, and/or the reaction crucible 114. The baffle 126 may filter or otherwise reduce impurities from the source material in a crystal growth process. The baffle 126 may provide for control of radiative heat transfer. The baffle 126 may include any of the baffles disclosed in U.S. patent application Ser. No. 18/962,454 filed on Nov. 27, 2024, which is incorporated herein by reference.

As shown in FIG. 1, the baffle 126 may be located on the source material, may be spaced apart from the source material 120 and/or the seed material 126, or may be proximate the seed material 122. In some embodiments, the system 112 may include any number of baffles 126 without deviating from the scope of the present disclosure.

In the embodiment illustrated in FIG. 1, a seed holder 124 is used to hold seed material 122. Seed holder 124 is securely attached to reaction crucible 114 in an appropriate fashion using conventional techniques. For example, in the orientation illustrated in FIG. 1, seed holder 124 is attached to an uppermost portion of reaction crucible 114 to hold seed material 122 in a desired position. In one embodiment, seed holder 124 is fabricated from carbon. The attachment of the seed material (i.e., a seed wafer) to a corresponding seed holder within a sublimation system may be made, for instance, a uniform thermal contact. Various techniques may be used to implement a uniform thermal contact. For example, the seed material may be placed in direct physical contact with the seed holder, or an adhesive may be used to fix the seed material to the seed holder, so as to ensure that conductive and/or radiative heat transfer is uniform over substantially the entire area between the seed and the seed holder. Alternately, a wafer holder comprising a controlled gap structure may be used to define and maintain a desired separation gap between the seed material and the seed holder. It will also be understood by those skilled in the art that the use of a controlled gap structure may require a protective backside surface coating on the seed material (i.e., on the surface opposite to the growth surface) so that the seed material will not inadvertently sublimate during the growth process. In various embodiments, a controlled gap structure may be used to form a separation distance between the seed material and seed holder of 10 μm or less, 5 μm or less, 2 μm or less, and where practically possible less than 1 μm. The thickness of the seed material 122 may be from about 0.1 mm to about 5 mm, such as from about 0.2 μm to about 2 mm, such as from about 0.3 mm to about 1 mm, such as from about 0.4 mm to about 0.7 mm.

In some embodiments, the sublimation system may include a second source material. The second source material can be a solid shaped source material according to any of the embodiments described herein or may be another type of silicon carbide vapor source material. The second source material may be located anywhere within the crucible. For example, it may be spaced axially, radially, or concentrically from a first source structure.

Further, the sublimation system 112 may optionally include a source material holder 130. The source material holder 130 may be, for example, one or more graphite components within the crucible that brace or support the source material. In some embodiments, the source material holder 130 may be attached to the inner walls of the reaction crucible 114, as shown in FIG. 1.

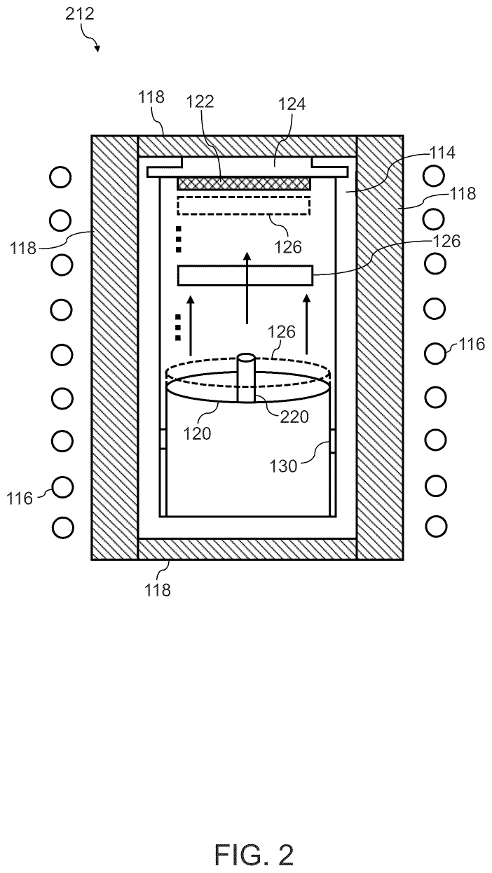

In one example embodiment, shown in FIG. 2, sublimation system 212 may be similar to that shown in FIG. 1, but also includes an inlet 220 for introducing a dopant (e.g., N₂) to the reaction crucible 114. The inlet 220, may be, for example, a tube, pipe, vent, or the like. In some embodiments, the source material 120 may surround the inlet 220. For example, in some embodiments, the source material structure may include a channel through which the inlet 220 is provided. In other embodiments, the source material structure may include a plurality of subcomponents (attached or detached) which surround the inlet 220. The inlet 220 may be connected to a dopant-containing gas source (not shown) and configured to introduce the dopant-containing gas to the reaction crucible 114. An example of a dopant-containing gas is nitrogen. In some embodiments, the system may include a baffle 126. The baffle 126 may provide a mechanism for the transport of source vapor during sublimation of the source material 120. The baffle 126 may have any spatial orientation relative to the source material 120, the seed crystal 122, and/or the reaction crucible 114. The baffle 126 may filter or otherwise reduce impurities from the source material in a crystal growth process. The baffle 126 may provide for control of radiative heat transfer. The baffle 126 may include any of the baffles disclosed in U.S. patent application Ser. No. 18/962,454 filed on Nov. 27, 2024, which is incorporated herein by reference.

As shown in FIG. 2, the baffle 126 may be located on the source material, may be spaced apart from the source material 120 and/or the seed material 126, or may be proximate the seed material 122. In some embodiments, the system 212 may include any number of baffles 126 without deviating from the scope of the present disclosure.

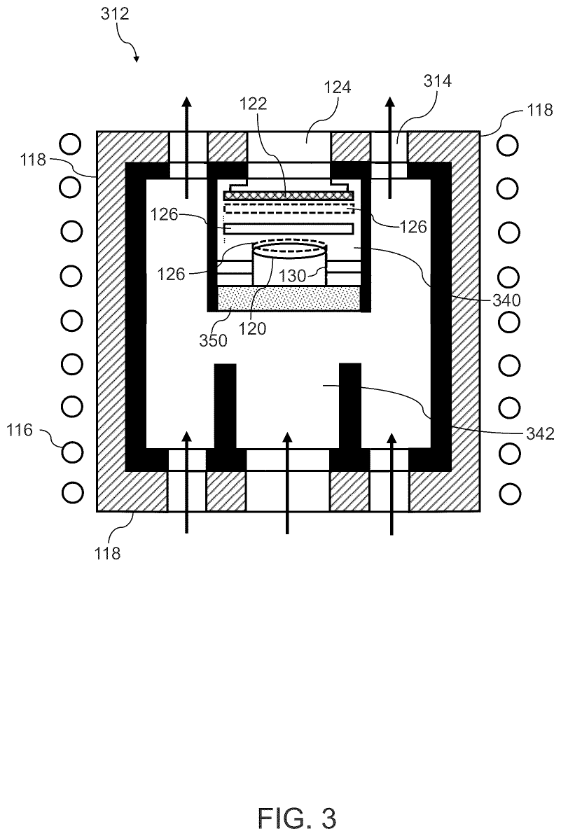

In another example embodiment, shown in FIG. 3, sublimation system 312 may be a continuous feed PVT (CF-PVT) system. In the CF-PVT system, the reaction crucible 314 may include an upper chamber 340 and a lower chamber 342. The upper chamber 340 may include the solid source material 120 and the seed material 122. The upper chamber 340 may be separated from the lower chamber 342 by a foamed structure 350. The foamed structure 350 may be formed, for example, from a gas-permeable graphite foam. The source material 120 may be placed on the foamed structure 350 within the upper chamber. A gaseous silicon source (e.g., trimethylsilane diluted in argon) may be supplied to the lower chamber. As the gaseous silicon source flows through the foamed structure 350, it may react with a carbon source within the foamed structure 350 (e.g., graphite) to form silicon carbide. The CF-PVT system combines the PVT process for the growth of single crystals and HTCVD process for the in-situ formation and continuous feeding of high purity polycrystalline source. The CF-PVT system may be particularly useful for growing 3C silicon carbide. In some embodiments, rather than structure 350 being a foamed structure, it may be a solid disk with holes, slots, etc. In some embodiments, the system may include a baffle 126. The baffle 126 may provide a mechanism for the transport of source vapor during sublimation of the source material 120. The baffle 126 may have any spatial orientation relative to the source material 120, the seed crystal 122, and/or the reaction crucible 114. The baffle 126 may filter or otherwise reduce impurities from the source material in a crystal growth process. The baffle 126 may provide for control of radiative heat transfer. The baffle 126 may include any of the baffles disclosed in U.S. patent application Ser. No. 18/962,454 filed on Nov. 27, 2024, which is incorporated herein by reference.

As shown in FIG. 3, the baffle 126 may be located on the source material, may be spaced apart from the source material 120 and/or the seed material 126, or may be proximate the seed material 122. In some embodiments, the system 312 may include any number of baffles 126 without deviating from the scope of the present disclosure.

In any of the embodiments shown in FIGS. 1-3 or any other suitable sublimation growth systems, reaction crucible 114 may be implemented in a number of different shapes and may hold one or more source materials accordingly. Thus, while embodiments of the present disclosure may be illustrated with certain reaction crucible designs, the scope of the present disclosure is not limited to such designs but will find application in different sublimation systems using many different types of reaction crucibles.

For any of the crystal growth systems provided herein, one or more parts of the crystal growth system or the source material may be 3D printed, such as disclosed in U.S. Provisional Application Ser. No. 63/689,298, which is incorporated herein by reference.

This disclosure is intended to cover sources that are shaped or otherwise designed (e.g., layered) to achieve certain characteristics to improve SiC crystal growth by designing the source based on desired properties (e.g., sublimation rate, sublimation direction, vapor flow, etc.) while considering temperature gradients/regions in the growth chamber, desired crystal characteristics etc., and/or changing or maintaining these growth or crystal characteristics based on the stage of the crystal growing process (e.g., initial growth on the seed, intermediate phase, and end of crystal growth). More complex figures are shown to exemplify that the sources can have simple or very complicated designs. Any of the sources shown in these figures can show features that can be used in the configuration shown or together with features of other figures. Furthermore, these sources are shown as single figures, but the sources can comprise a single or multiple of these sources (whether the same design or different) as well as sources using features from different figures to form a source or multiple sources that are not expressly shown in the figures.

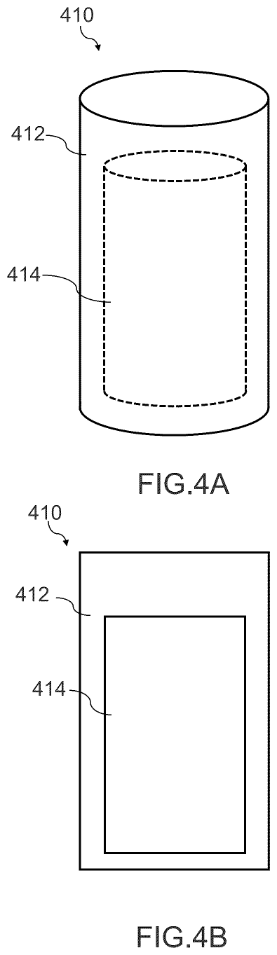

Various example embodiments of the source material structure 120 are illustrated in FIGS. 4A-16 and 22-23B, as described below.

One example embodiment of the source material structure is shown in FIGS. 4A and 4B. FIG. 4B depicts a cross-section of the source material structure 410 shown in FIG. 4A as if vertically divided down the middle of FIG. 4A. The structure 410 contains an outer layer 412 and an inner layer 414. Both layers contain silicon carbide. The outer layer 412 is different from the inner layer 414 in at least one property. The property may be, for example, the polytype of silicon carbide, the material density of the silicon carbide, the composition (e.g., when one or more materials other than silicon carbide are included in one or both layers), the purity of the silicon carbide, the sublimation rate, the total porosity of the silicon carbide, the form of silicon carbide (e.g., shaped solid or powdered silicon carbide) and the like. In some embodiments, both layers may be formed as shaped solids. In other embodiments, one layer may be a powder layer and one layer may be a shaped solid layer. For example, in some embodiments, the outer layer may be a shaped solid and the inner layer may be a powder contained by the outer layer.

As used herein, adjacent layers can be discrete or can be separated by a boundary area where there is a gradient in the one or more differing properties from one layer to the adjacent layer.

When the differing property is the polytype, one layer may have any silicon carbide polytype and the other layer may have any other silicon carbide polytype (i.e., any polytype other than that of the outer layer). For example, in one embodiment, the first layer comprises 3C SiC and the second layer comprises 15R SiC. In another embodiment, the first layer comprises 3C SiC and the second layer comprises 4H SiC. In another embodiment, the first layer comprises 3C SiC and the second layer comprises 6H SiC. In another embodiment, the first layer comprises 3C SiC and the second layer comprises 21R SiC. In another embodiment, the first layer comprises 15R SiC and the second layer comprises 4H SiC. In another embodiment, the first layer comprises 15R SiC and the second layer comprises 6H SiC. In another embodiment, the first layer comprises 4H SiC and the second layer comprises 6H SiC. In another embodiment, the first layer comprises 15R SiC and the second layer comprises 21R SiC. In another embodiment, the first layer comprises 4H SiC and the second layer comprises 21R SiC. In another embodiment, the first layer comprises 6H SiC and the second layer comprises 21R SiC. In another embodiment, the first layer comprises 3C SiC and the second layer comprises 2H SiC. In another embodiment, the first layer comprises 2H SiC and the second layer comprises 4H SiC. In another embodiment, the first layer comprises 2H SiC and the second layer comprises 6H SiC. In another embodiment, the first layer comprises 2H SiC and the second layer comprises 21R SiC. In another embodiment, the first layer comprises 2H SiC and the second layer comprises 15R SiC. In some embodiments, the first layer is the outer layer 412 and the second layer is the inner layer 414. In other embodiments, the first layer is the inner layer 414 and the second layer is the outer layer 412.

When the differing property is the material density of the silicon carbide, one layer has a higher material density than the other layer. For example, the material density of the first layer may be from about 1.0 g/cm³ to about 2.6 g/cm³, such as from about 1.5 g/cm³ to about 2.2 g/cm³, such as from about 1.8 g/cm³ to about 2.1 g/cm³, and the material density of the second layer may be from about 2.0 g/cm³ to about 3.21 g/cm³, such as from about 2.3 g/cm³ to about 3.1 g/cm³, such as from about 2.6 g/cm³ to about 3.0 g/cm³. The ratio of the material density of the second layer to that of the first layer is greater than 1, such as about 1.2 or greater, such as about 1.4 or greater, such as about 1.6 or greater, such as about 1.8 or greater, such as about 2.0 or greater, such as about 2.2 or greater, such as about 2.4 or greater, such as about 2.6 or greater, such as about 2.8 or greater. In one example embodiment, the first layer may be formed by binding or sintering silicon carbide particles having a larger median diameter than those forming the second layer. In some embodiments, one of the layers may contain silicon carbide powder while the other is a shaped solid. In some embodiments, one of the layers may contain a graphite converted silicon carbide while the other is a shaped solid containing silicon carbide particles and optionally a binder. In some embodiments, the first layer is the outer layer 412 and the second layer is the inner layer 414. In other embodiments, the first layer is the inner layer 414 and the second layer is the outer layer 412. When the outer layer is less dense than the inner layer, the outer layer may serve as a filter for the silicon carbide vapor sublimated from the inner layer, while also serving as a secondary source material.

As used herein, the material density is the ratio of mass of solid material to the volume of the solid material excluding open pores (i.e., skeletal density). The volume includes the volume of closed pores. However, the closed pores do not include any voids formed in a shaped solid structure. As used herein, a void means a cavity within the interior of the structure (e.g., a shaped, non-random cavity intentionally formed when shaping the source material). Voids generally have a volume of about 0.065 mm³ or more, such as about 0.1 mm³ or more, such as about 0.5 mm³ or more, such as about 1 mm³ or more, such as about 10 mm³ or more, such as about 100 mm³ or more, such as about 1000 mm³ or more, such as about 4000 mm³ or more.

When the differing property is the composition of the silicon carbide, one layer contains at least one component in a different concentration than the other layer. For example, the first layer may contain a dopant while the second layer does not. In another embodiment, the first layer comprises a dopant and the second layer comprises a different dopant. Suitable dopants include, for example, vanadium, aluminum, or boron. However, any dopant may be used. In another embodiment, the first layer may be a graphite converted silicon carbide while the second layer contains sintered silicon carbide particles or silicon carbide particles and a binder. In this regard, the graphite converted layer may contain unconverted graphite and/or unreacted silicon and the other layer may comprise only silicon carbide or silicon carbide and a binder. Similarly, the differing property may be the purity of the silicon carbide in each layer. For example, the first layer may have a higher silicon carbide concentration than the second layer. In some embodiments, the first layer is the outer layer 412 and the second layer is the inner layer 414. In other embodiments, the first layer is the inner layer 414 and the second layer is the outer layer 412.

Similarly, the differing property may be the concentration of an impurity within the silicon carbide. For example, the ratio of impurities in the first layer to the second layer may be greater than 1, such as about 1.5 or more, such as about 2 or more, such as about 5 or more, such as about 10 or more. In some embodiments, the first layer is the outer layer 412 and the second layer is the inner layer 414. In other embodiments, the first layer is the inner layer 414 and the second layer is the outer layer 412. Impurities include, for example, vanadium, boron, aluminum, nitrogen, cerium, germanium, and the like.

When the differing property is the sublimation rate of silicon carbide, one layer has a faster sublimation rate than the other. For example, the ratio of the sublimation rate of the first layer to the sublimation rate of the second layer may be greater than 1, such as about 1.1 or greater, such as about 1.3 or greater, such as about 1.5 or greater, such as about 1.7 or greater, such as about 2 or greater, when measured at 2000° C. In some embodiments, the outer layer may have a slower sublimation rate than the inner layer. In other embodiments, the outer layer may have a faster sublimation rate than the inner layer. Sublimation rate may be affected by the layer's density, porosity, surface area, and the like.

When the differing property is the total porosity of the silicon carbide, one layer has a higher total porosity than the other layer. For example, the total porosity of the first layer may be from about 5% to about 60%, such as from about 20% to about 50%, and the total porosity of the second layer may be from about 50% to about 90%, such as from about 60% to about 80%. The ratio of the total porosity of the second layer to that of the first layer is greater than 1, such as about 1.2 or greater, such as about 1.5 or greater, such as about 1.7 or greater, such as about 2 or greater, such as about 2.2 or greater, such as about 2.5 or greater, such as about 2.7 or greater, such as about 3 or greater, such as about 3.5 or greater. In some embodiments, the first layer is the outer layer 412 and the second layer is the inner layer 414. In other embodiments, the first layer is the inner layer 414 and the second layer is the outer layer 412. As used herein, the total porosity means the percentage of open pores and closed pores in the material relative to the bulk volume of the material.

In some embodiments, the outer layer 412 can have features (e.g., density, porosity, channels, pores, voids, and the like) such that the second layer acts as a filter for the inner layer 414. For instance, the outer layer 412 can have properties that facilitate filtering or direction of sublimation from the inner layer 414 to the seed. In this way, the outer layer 412 can act as a source material and as a filter for sublimation of silicon carbide vapor from the inner layer 414.

FIGS. 4A and 4B depicts a two-layer structure for purposes of illustration and discussion. Those of ordinary skill in the art, using the disclosure provided herein, will understand that the source material can include more than two layers, such as three layers, such as four layers, such as ten layers, such as dozens of layers, such as hundreds of layers, without deviating from the scope of the present disclosure.

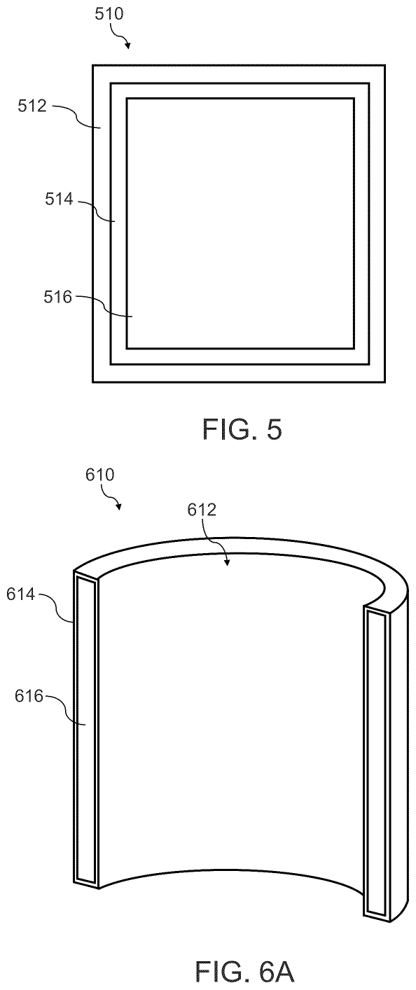

For instance, FIG. 5 shows a cross-section of another example embodiment of the source material structure. The structure 510 is a three-layered structure containing outer layer 512, middle layer 514, and inner layer 516. Similar to the embodiment shown in FIGS. 4A and 4B, at least one of the three layers is different from the others in at least one property. The property may be any of those described with respect to FIGS. 4A and 4B. In some embodiments, the inner layer 516 and the outer layer 512 have the same properties as each other and the middle layer 514 is different in at least one property from the inner layer 516 and the outer layer 512. In other embodiments, all three layers are different from each other in at least one property. As discussed above, it should also be understood, using the disclosures provided herein, that the source material structure is not limited to having only two layers (e.g., FIGS. 4A and 4B) or three layers (e.g., FIG. 5), and that it may have any feasible number of layers.

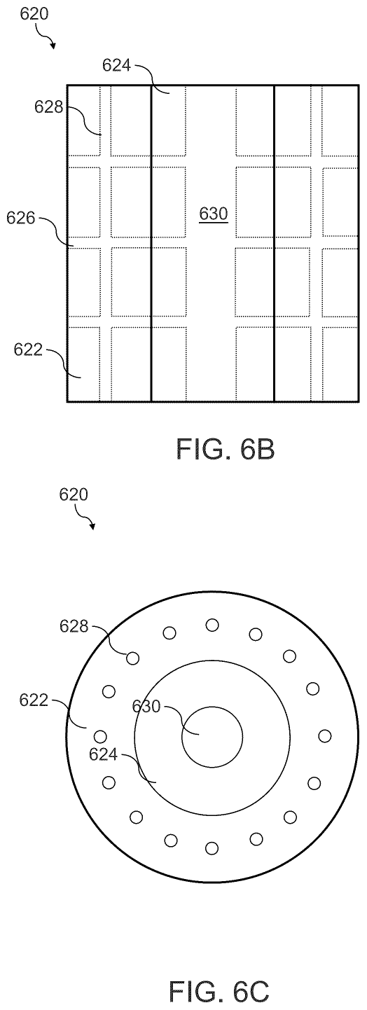

FIG. 6A shows a cross-section of another example embodiment of the source material structure. The structure 610 is a cylindrical structure with a channel 612 through the middle. The structure 610 is a two-layer structure containing an outer layer 614 and an inner layer 616. Inner layer 616 and outer layer 614 are different from each other in at least one property and may have any of the properties described above for layers 412 and 414 with respect to FIGS. 4A and 4B.

FIG. 6B shows a cross-section of another example embodiment of the source material structure. The structure 620 is a cylindrical structure with an optional channel 630 through the middle. The structure 620 is a two-layer structure containing an outer layer 622 and an inner layer 624. Inner layer 624 and outer layer 622 are different from each other in at least one property and may have any of the properties described above for layers 412 and 414 with respect to FIGS. 4A and 4B. In some embodiments, the structure 620 may contain a central channel 630, peripheral vertical channels 628, and horizontal channels 626. The various channels may be designed based on the desired vapor flow paths and flowrates. In some embodiments, the structure 620 may only contain the vertical channels 630 and 628, In some embodiments, the structure 620 may only contain the horizontal channels 626. In some embodiments, the structure 620 may not contain any channels and may be a solid two layer structure. It should also be understood that channels, such as the vertical and horizontal channels shown in FIG. 6B or angled (i.e., not perpendicular or parallel to the vertical axis) channels, may be formed in any of the source structures described herein. Channels may allow for enhanced sublimation, particularly for inner layers, and may direct the sublimated vapor within the crucible as desired.

A top view of the structure 620 is shown in FIG. 6C. It can be seen that the peripheral vertical channels 628 and the central channel 630 extend up through the top surface of the structure, providing a vapor flow path up toward the seed material and/or growing crystal. Structures with concentric layers such as that shown in FIGS. 6A and 6B may be used when there is a desire to have different sublimation properties or crystal properties in the central portion of the crucible compared to the peripheral portions.

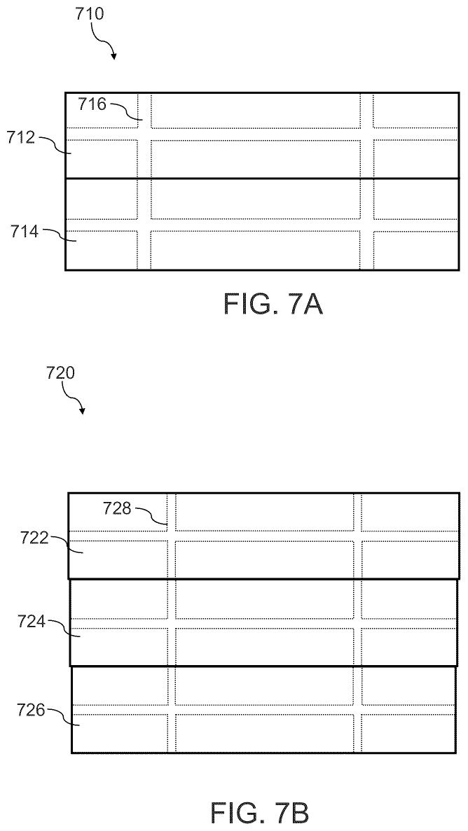

FIG. 7A shows another example embodiment of the source material structure. The structure 710 is a two-layered structure containing upper layer 712 and lower layer 714. Upper layer 712 and lower layer 714 are different from each other in at least one property and may have any of the properties described above for layers 412 and 414 with respect to FIGS. 4A and 4B.

FIG. 7B shows another example embodiment of the source material structure. The structure 720 is a three-layered structure containing upper layer 722, middle layer 724, and lower layer 726. Upper layer 722 and lower layer 726 may be different from the middle layer 724 in at least one property and may have any of the properties described above for layers 412 and 414 with respect to FIGS. 4A and 4B. In some embodiments, upper layer 722 and lower layer 726 have the same properties as each other. In other embodiments, all three layers differ from each other in at least one property. In some embodiments, it may be desirable to have a three layered source structure having the same material in the top and bottom layers and a different material (i.e., differing in at least one property) in the middle layer if, for example, there is a known hot spot or cold spot within the crucible in the location of the middle layer. In this regard, if the middle layer is in a hot spot, then it may be desirable to form the middle layer with properties giving tending to provide slower sublimation compared to the top and bottom layers.

Again, in some embodiments, the source material structure may contain channels, such as channels 716 in FIG. 7A and channels 728 in FIG. 7B, which can be designed to transport sublimated vapor as desired within the crucible. For example, each layer may have at least one channel completely contained within that layer, such as the horizontal channels shown in FIGS. 7A and 7B. The structure may contain other channels extending through multiple layers, such as the vertical channels shown in FIGS. 7A and 7B.

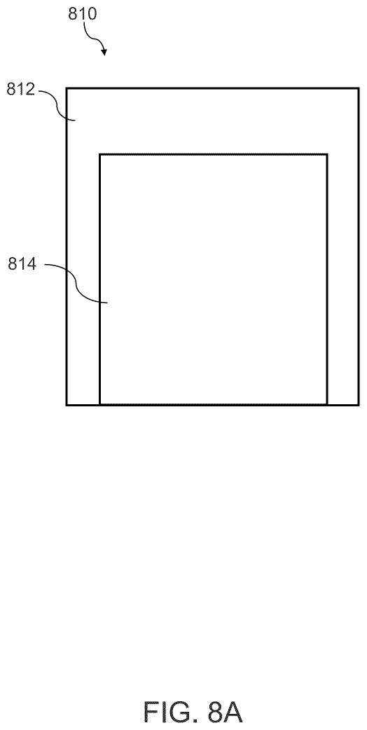

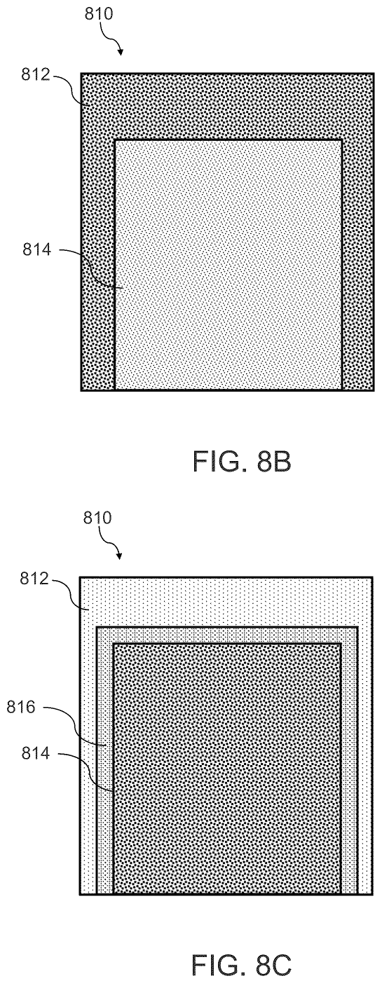

FIG. 8A shows another example embodiment of the source material structure. The structure 810 is a two-layered structure containing an outer layer 812 and an inner layer 814. Outer layer 812 and inner layer 814 are different from each other in at least one property and may have any of the properties described above for layers 412 and 414 with respect to FIGS. 4A and 4B. As shown in FIG. 8B, the inner layer 814 and the outer layer 812 may both be formed from powders differing in at least one property. For example, the powder of inner layer 814 may contain a dopant while the powder in the outer layer 812 does not contain a dopant, contains a different dopant from inner layer 814, or contains the same dopant as inner layer 814 in a different concentration.

FIG. 8C shows an example embodiment in which there is a transition area or boundary layer 816 between the inner layer 814 and the outer layer 812. The transition area or boundary layer 816 may be a portion in which there is a gradient in the at least one differing property from the inner layer 814 to the outer layer 812. For example, in some embodiments, the inner layer 814 may contain a dopant in a first concentration, the outer layer 812 may contain the dopant in a second concentration, and the boundary layer 816 may contain a concentration of the dopant between the first concentration and the second concentration, and the concentration within the boundary layer 816 may gradually change within the boundary layer 816.

In some embodiments, a first layer at least partially surrounds a second layer. For example, in FIGS. 4A and 4B outer layer 412 fully surrounds inner layer 414. Similarly, in FIG. 5 outer layer 512 fully surrounds middle layer 514, which fully surrounds inner layer 516. Similarly, in FIG. 6, outer layer 614 fully surrounds inner layer 616. In FIGS. 8A-8C, outer layer 812 partially surrounds inner layer 814. In other embodiments, a first layer and a second layer are both flat and stacked, such as layers 712 and 714 in FIG. 7.

In any of the layered embodiments, the layers may have any suitable thickness. For example, the thickness of any layer may be about 1 μm or more, such as 5 μm or more, such as 20 μm or more, such as 50 μm or more, such as 100 μm or more, such as 1 mm or more, such as 5 mm or more, such as 10 mm or more, such as 5 cm or more. While the thickness of any layer is not limited, it may be less than 50 cm, such as less than 30 cm, such as less than 10 cm, such as less than 1 cm, such as less than 5 mm, such as less than 1 mm, such as less than 100 μm, such as less than 50 μm. In some embodiments, the source material structure may have a core inner layer at least partially surrounded by a relatively thin outer layer. For example, the inner layer may have a thickness (e.g., diameter) from about 1 mm or more, such as about 5 mm or more, such as about 1 cm or more, such as about 5 cm or more, such as about 10 cm or more, and the outer layer may have a thickness from about 1 μm to about 1 mm. In some embodiments, the outer layer is a coating layer on the inner layer.

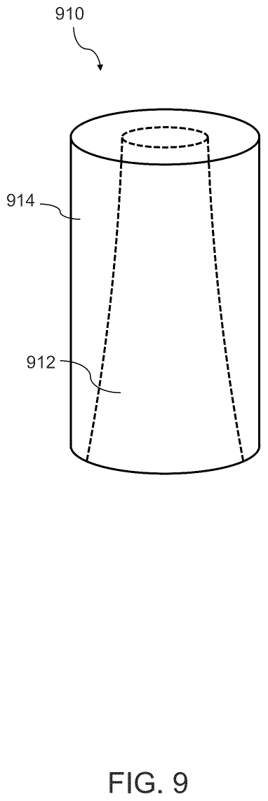

In some embodiments, the source material structure contains a dopant. As described with respect to FIGS. 4A and 4B, the dopant can be contained in one or more layers in a layered source material structure. In other embodiments, the source material structure may not be layered. For example, it may be a shaped solid source material having uniform properties throughout. For instance, the source material may have one or more dopants uniformly distributed throughout the structure. Alternatively, it may be a shaped solid that does not have uniform properties and does not have distinctly different layers. For example, FIG. 9 shows a shaped solid source material structure 910 having a cylindrical structure and a dopant-rich central portion 912 and a dopant-poor peripheral portion 914. In some embodiments, there may be gradual gradient in dopant concentration increasing from the dopant-poor portion 914 to the dopant-rich portion 912. In other embodiments, the dopant-poor region 914 may be essentially free of dopants. In other embodiments, the dopant-poor region is the central portion 912 and the dopant-poor region is the peripheral portion 914. Other suitable dopant distributions may be used without deviating from the scope of the present disclosure.

As mentioned above, suitable dopants include vanadium, aluminum, and boron. Regardless of the specific dopant used, the dopant may be dispersed directly within the silicon carbide source material structure in elemental form or in the form of a compound containing the dopant. In other embodiments, the dopant is coated onto carrier particles which are then dispersed within the silicon carbide source material structure. For example, the carrier particles may comprise graphite. In this regard, in some embodiments, the dopant may be coated or annealed onto graphite particles which are incorporated into the source material structure. The dopant-modified graphite particles may be incorporated by being used to form a graphite preform which is then reacted with a silicon-containing gas source to form a graphite converted silicon carbide or by being mixed with silicon carbide powder that is then formed into a shaped solid by sintering or using a binder.

With reference again to FIGS. 1-3, in some embodiments, source material 120 contains silicon carbide having a different polytype from the silicon carbide of seed material 122. For example, in one embodiment, the source material comprises 3C SiC and the seed material comprises 15R SiC. In another embodiment, the source material comprises 3C SiC and the seed material comprises 4H SiC. In another embodiment, the source material comprises 3C SiC and the seed material comprises 6H SiC. In another embodiment, the source material comprises 3C SiC and the seed material comprises 21R SiC. In another embodiment, the source material comprises 15R SiC and the seed material comprises 4H SiC. In another embodiment, the source material comprises 15R SiC and the seed material comprises 6H SiC. In another embodiment, the source material comprises 15R SiC and the seed material comprises 21R SiC. In another embodiment, the source material comprises 4H SiC and the seed material comprises 6H SiC. In another embodiment, the source material comprises 4H SiC and the seed material comprises 21R SiC. In another embodiment, the seed material comprises 6H SiC and the source material comprises 21R SiC. In another embodiment, the seed material comprises 3C SiC and the source material comprises 15R SiC. In another embodiment, the seed material comprises 3C SiC and the source material comprises 4H SiC. In another embodiment, the seed material comprises 3C SiC and the source material comprises 6H SiC. In another embodiment, the seed material comprises 3C SiC and the source material comprises 21R SiC. In another embodiment, the seed material comprises 15R SiC and the source material comprises 4H SiC. In another embodiment, the seed material comprises 15R SiC and the source material comprises 6H SiC. In another embodiment, the seed material comprises 15R SiC and the source material comprises 21R SiC. In another embodiment, the seed material comprises 4H SiC and the source material comprises 6H SiC. In another embodiment, the seed material comprises 4H SiC and the source material comprises 21R SiC. In another embodiment, the seed material comprises 6H SiC and the source material comprises 21R SiC. In another embodiment, the source material comprises 3C SiC and the seed material comprises 2H SiC. In another embodiment, the source material comprises 2H SiC and the seed material comprises 4H SiC. In another embodiment, the source material comprises 2H SiC and the seed material comprises 6H SiC. In another embodiment, the source material comprises 2H SiC and the seed material comprises 21R SiC. In another embodiment, the seed material comprises 3C SiC and the source material comprises 2H SiC. In another embodiment, the seed material comprises 2H SiC and the source material comprises 4H SiC. In another embodiment, the seed material comprises 2H SiC and the source material comprises 6H SiC. In another embodiment, the seed material comprises 2H SiC and the source material comprises 21R SiC. In another embodiment, the source material comprises 2H SiC and the seed material comprises 15R SiC. In another embodiment, the source material comprises 15R SiC and the seed material comprises 2H SiC.

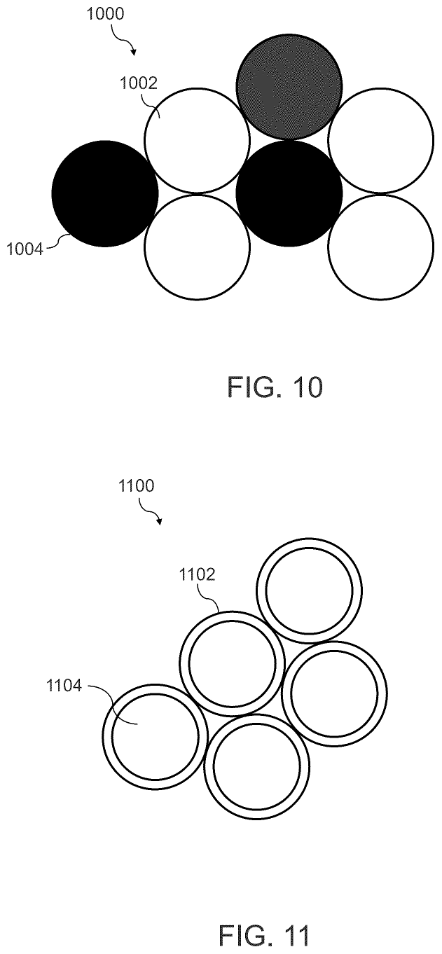

In some embodiments, the source material structure comprises a silicon carbide powder. As explained above, the powder may form a layer in combination with a shaped solid structure or may be contained within a shaped solid structure. In some embodiments, the source material may comprise powder without any shaped solid source material structure. For example, the source material may comprise a powder bed alone or a powder contained by non-silicon carbide materials (e.g., graphite). In any case, FIGS. 10-12 show example embodiments of powdered source materials. These can be part of a source material including shaped solid source materials or can be powdered source materials used alone.

As shown in FIG. 10, a source material powder 1000 can include a first silicon carbide powder type 1002 and a second silicon carbide powder type 1004. The first powder type 1002 differs from the second powder type 1004 in at least one property. The properties may be any of those described above with reference to layers having different properties. For example, the first powder type 1002 may contain a first polytype of silicon carbide and the second powder type 1004 may contain a second polytype of silicon carbide. In some embodiments, the first powder type 1002 may contain a dopant and the second powder type 1004 may not contain a dopant or may contain a different dopant from powder type 1002.

In some embodiments, as shown in FIG. 11, a source material powder 1100 may contain silicon carbide powder particles having a core-shell structure containing a core 1104 and a shell 1102. The core 1104 may differ from the shell 1102 in at least one property, such as any of those described above with reference to layers having different properties. For example, the powder particles may have a shell containing a dopant and a core which does not contain a dopant or contains a different dopant from the shell. In some embodiments, the core and shell may have different sublimation rates. For example, the shell may have a slower sublimation rate than the core. Alternatively, the shell may have a faster sublimation rate than the core. The core-shell type particles can be used to create a crystal structure which has non-uniform properties, as the shell layer may tend to sublimate first, followed by the core layer.

In some embodiments, different particles may have different core and shell layers from each other. For example, in some embodiments, some particles have cores having a set of properties A and other particles have cores having a set of properties B differing from A in at least one property. The shell layers on cores A and B may have different properties from the core layers, as described above. However, the shell layers on the particles with A cores may be different from the shell layers on the particles with B cores, such that the A cores are exposed at a different time than the B cores. For example, the shell layers on the A cores may be thicker than the shell layers on the B cores. In this regard, the B cores may be exposed and thus sublime quicker than the A cores, as the shells on the A cores may take longer to evaporate than the shells on the B cores. Such an embodiment may be used when the differing core property is a dopant type. For example, if it were desired to provide one type of dopant toward the beginning of crystal growth and another dopant toward the end, the particles with the dopant desired to be used toward the end may have thicker shells than the particles containing the dopant desired to be used toward the beginning of crystal growth.

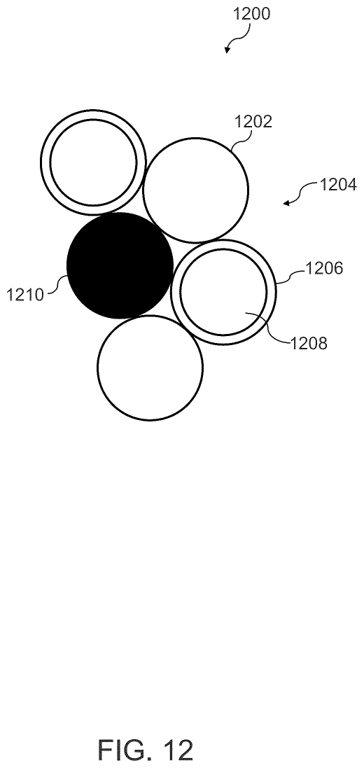

As shown in FIG. 12, the source material powder 1200 may contain some particles 1204 having a core-shell structure containing a core 1208 and a shell 1206 and other particles 1202, 1210 which have a uniform structure. Particles 1202 and 1210 may vary in at least one property. Similarly, core 1208 may differ from shell 1206 in at least one property. It should be understood that the source material powder may contain further types of uniform or core-shell particles differing from particles 1202, 1206, and 1210 in at least one property.

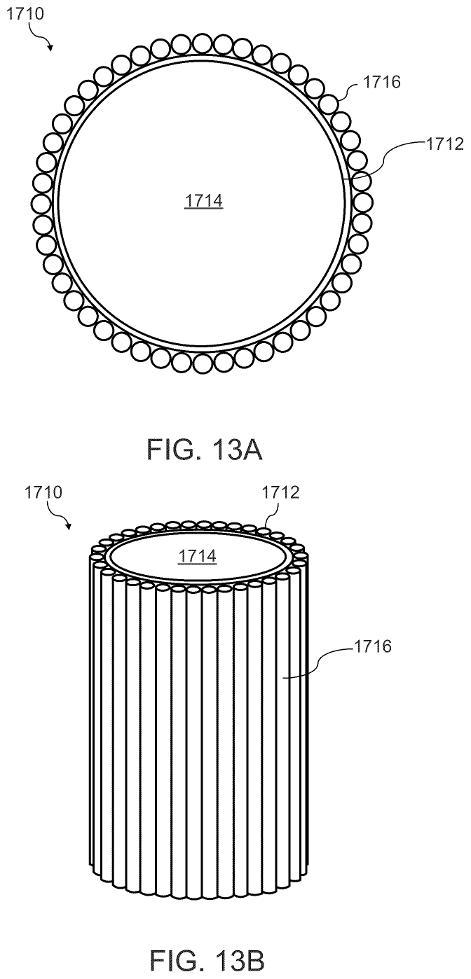

In some embodiments, rather than multiple layers within a single structure, the source material may contain multiple components, which may or may not be connected or adhered to each other. In such embodiments, at least one component may differ in at least one property from another component. An example embodiment of a such a source material structure is shown in FIGS. 13A and 13B. FIG. 13A shows a top view of the composite structure 1710, which contains a cylindrical base 1712 having a channel 1714 running between its top to bottom surfaces to form a tubular structure. The tubular structure is surrounded by rods 1716. In some embodiments, the rods 1716 may be integral with the cylindrical base 1712. For example, they may be adhered to or monolithic with the cylindrical base 1712. In other embodiments, the rods 1716 are distinct from the cylinder 1712 and are only placed along its perimeter. FIG. 13B provides a different view of the source material structure 1710.

In some embodiments, the rods 1716 may be formed from silicon carbide and the cylindrical base 1712 may be formed from graphite. In other embodiments, the rods 1716 and the cylindrical base 1712 are formed from silicon carbide. In some embodiments, the cylindrical base 1712 is formed from silicon carbide differing in at least one property from the rods 1716. In another embodiment, one or more of the silicon carbide rods 1716 may differ in at least one property from one or more other rods 1716.

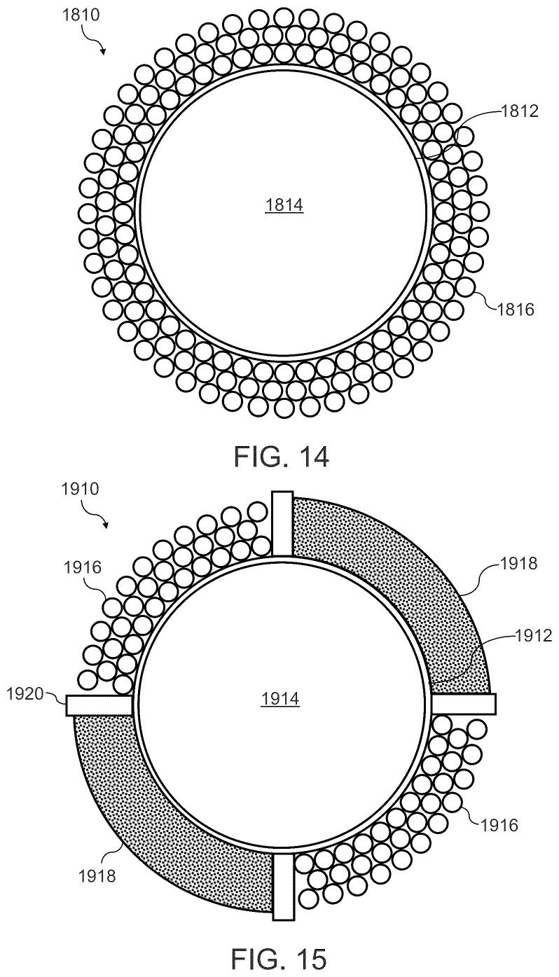

Another example embodiment of a multicomponent shaped source material structure is shown in FIG. 14. The structure 1810 is similar to that shown in FIG. 10 except that more rods 1816 are placed around the tube formed from cylindrical base 1812 and channel 1814 such that there are multiple rows of rods 1816. Again, the rods 1816 may vary in properties from each other or from the tube if the tube also contains silicon carbide.

Another example embodiment of a multicomponent shaped source material structure is shown in FIG. 15. The structure 1910 is similar to that shown in FIG. 11 except that sections of rods 1916 and sections of silicon carbide powder 1918 surround the tube formed from cylindrical base 1912 and channel 1914. In some embodiments, the powder sections 1918 are sintered. The sections of rods 1916 and powder 1918 are separated by dividing walls 1920, which may be integral with or adhered to cylindrical base 1912. For example, in some embodiments, the cylindrical base 1912 and the dividing walls 1920 are formed from silicon carbide, and in other embodiments, they are formed from graphite. Again, the rods 1916 may vary in properties from each other or from the tube if the tube also contains silicon carbide. Further, the rods will inherently differ in at least one property (e.g., density) from the silicon carbide powder.

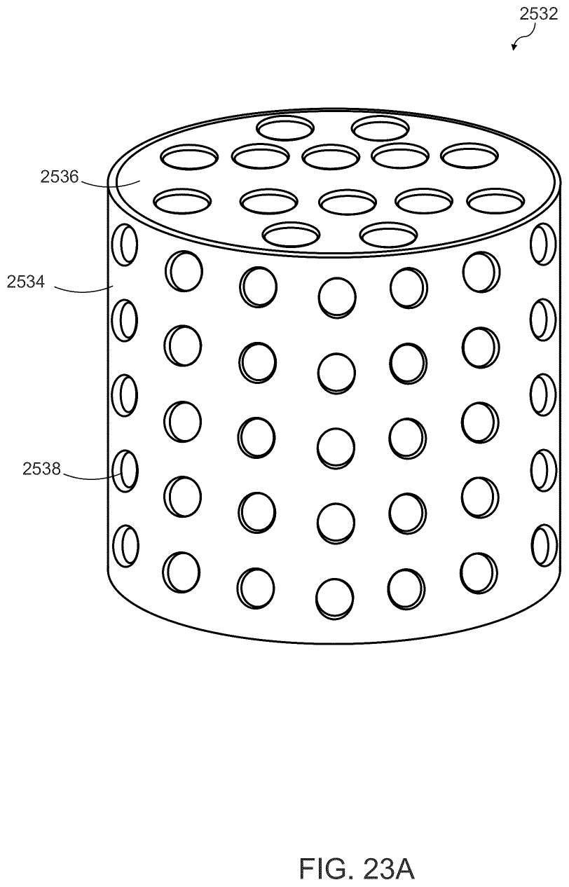

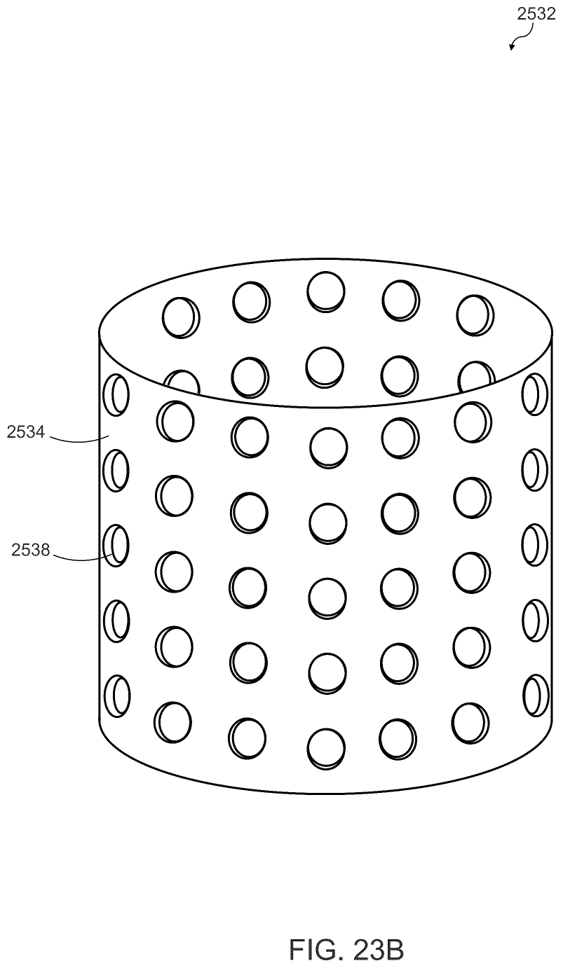

The cylindrical bases 1712, 1812, and 1912 shown in FIGS. 13A-15 can be the same as the retention member shown in FIG. 23B and can have any of the holes, pores, and variations described below with respect to FIG. 23B.

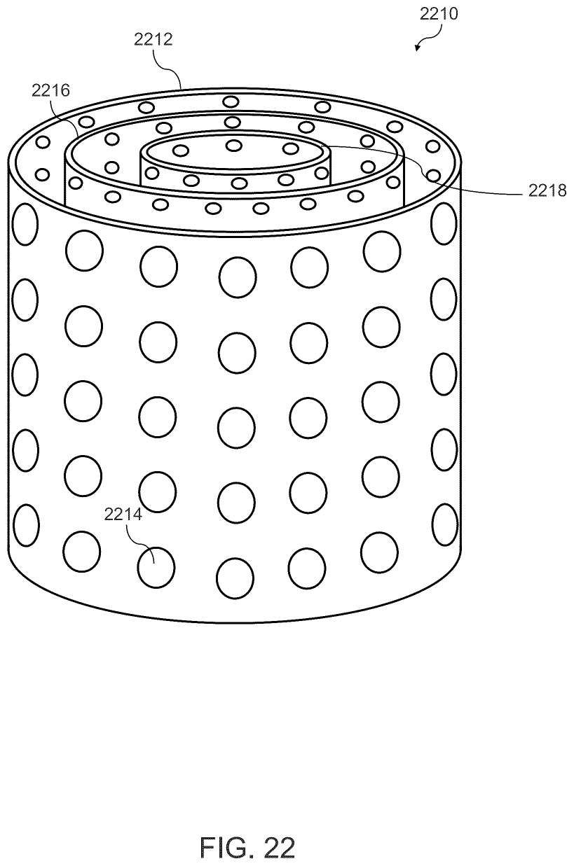

Another example embodiment of a multicomponent shaped source material structure is shown in FIG. 22. The structure 2210 contains multiple concentric tubular structures (2212, 2216, and 2218) each containing numerous channels 2214 within their walls. The gaps between the various concentric tubular structures may be filled with SiC powder. The channels 2214 allow for efficient radial flow of heat and/or vapor. The concentric tubular structures may be formed from SiC and act as a source material or may be formed from graphite or a ceramic material to act as a powder retention mechanism, which may divert the vapor flow as desired within the crucible. The various powders may be the same or may differ from each other in at least one property, as described above. For example, the powder between structures 2212 and 2216 may be different in at least one property from the powder between structures 2216 and 2218. In some embodiments, there may also be a powder within the innermost concentric structure 2218 that may be the same as or different from either of the other powders. The powders may also be in the form of core-shell particles, as described above.

In any of the embodiments described herein, the source material structure may be contained within a source retention mechanism, which can filter or divert the flow of vapor as desired within the crucible. Example embodiments of source retention mechanisms are shown in FIGS. 23A and 23B. in FIG. 23A, the source retention mechanism 2532 contains cylindrical side walls 2534, a cap 2536, and channels 2538 formed in the side walls 2534 and the cap 2536. As shown in FIG. 23A, the channels may all have the same or a similar diameter. In some embodiments, the diameters of the channels may be different and designed based on desired vapor flow paths and flowrates. For example, in some embodiments, the cap may have larger channels, or even one large central channel, relative to smaller or no peripheral channels.

The retention mechanism can be used to contain a source material, particularly when it is formed from multiple separate shaped solids (e.g., spheres) or if it contains powder. The channels 2538 allow sublimated vapor to escape into the main chamber of the reaction crucible where they can reach the seed material or growing crystal. The channels may be designed/located to control the vapor flow within the crucible. For example, they can direct the vapor to specific parts of the seed material or growing crystal. In some embodiments, the channels in the side walls 2534 may be omitted so that sublimated vapor can only exit through the channels in the cap 2536. In some embodiments, the cap 2536 may be omitted, as shown in FIG. 23B. In some embodiments, rather than, or in addition to, channels 2538, the source walls and/or cap of the retention mechanism may be made from a highly porous material that the sublimated vapor can escape through.

In some embodiments, it may be desired to restrict vapor flow from either the sides or the top. As such, the sides or top of the retention mechanism may be formed from a material with no or relatively low porosity. The retention mechanism may be formed from graphite, silicon carbide, or any other suitable material. When the retention mechanism is formed from silicon carbide, it may act as an additional source structure. The retention mechanism may be sized to fit within the inner walls of the crucible. The retention mechanism may contact the sidewalls of the crucible or may be spaced apart from them, leaving paths for vapor flow radially outward from the retention mechanism.

In any of the embodiments described herein, the source material structure contains silicon carbide. The silicon carbide structure can be formed in any suitable manner. For example, in some embodiments, the structure may be formed from silicon carbide powder and optionally a binder. The silicon carbide powder preferably has a median particle size (d50, as determined according to ISO 13320) sometimes referred to as grain size when formed into a solid, of about 5 μm or greater, such as about 10 μm or greater, such as about 15 μm or greater, such as about 20 μm or greater, such as about 30 μm or greater, such as about 50 μm or greater, such as about 70 μm or greater. In some embodiments, the grain size may be about 5 mm or less, such as about 1 mm or less, such as about 200 μm or less, such as about 100 μm or less, such as about 80 μm or less, such as about 60 μm or less, such as about 50 μm or less, such as about 40 μm or less, such as about 30 μm or less, such as about 20 μm or less. Examples of suitable binders include organic binders, such as polyethylene (e.g., HDPE), ethylene vinyl acetate, paraffin wax, organosilicons, preceramic polymers (e.g., polycarbosilane), polyvinylalcohol, acrylic resin, formaldehyde resin, furan resin, epoxy resin, phenolic resin, polysaccharides, cellulose derivatives, polyethylene glycol, UV curable polymer adhesives, supramolecular organometallic curable fluids, and the like. The binder may also be a sintering aid, such as carbon, aluminum, or boron. In some embodiments, to reduce or eliminate the boron content in the silicon carbide single crystal, boron is not used as a binder. Other suitable binders include, for example, cerium oxide, silicon nitride, and silica. In some embodiments, a binder including a dopant material (e.g., vanadium, boron, aluminum, nitrogen, cerium, germanium, and the like) may be used. For example, if it were desired to include cerium as a dopant in the grown crystal, cerium oxide may be used as a binder or if boron were desired as a dopant, boron carbide may be used as a binder.

The silicon carbide powder and optional binder may be shaped using any suitable method. For example, in some embodiments, it is extruded. In other embodiments, it is cast using a mold. In other embodiments, it is hot pressed (e.g., pressure sintered). The resulting structure may or may not be sintered after it is shaped.

In other embodiments, the silicon carbide structure is a graphite converted silicon carbide structure. Graphite converted silicon carbide can be produced by exposing a graphite preform to a silicon-containing gas, such as silicon monoxide, at a high temperature. This method is generally known as the chemical vapor reaction (CVR) process. For example, in one embodiment, a graphite preform having the shape of the desired silicon carbide source material structure is formed by molding, casting, extruding, 3D printing, or the like, and then exposed to a silicon containing gas (e.g., SiO or TEOS) at a high temperature, for example, from about 1400° C. to about 2000° C. The graphite preform may be converted to a silicon carbide structure having essentially the same shape as the graphite preform.

In one example embodiment, when the source material is a graphite converted silicon carbide structure, the graphite preform is a needle coke graphite structure. The graphite preform may have a material density from about 1.1 g/cm³ to about 1.9 g/cm³, such as about 1.4 g/cm³ to about 1.6 g/cm³, an open porosity (open pore volume/total pore volume) from about 90% to 100%, and a grain size from about 1 to about 20 micrometers. Graphite preforms having such properties provide good efficiency of graphite conversion into silicon carbide when exposed to a silicon-containing gas. The material density of the resulting silicon carbide structure may be about 1.4 g/cm³ or more, such as about 1.6 g/cm³ or more, such as about 1.8 g/cm³ or more, such as about 2.0 g/cm³ or more, such as about 2.2 g/cm³ or more, such as about 2.4 g/cm³ or more, such as about 2.6 g/cm³ or more, such as about 2.8 g/cm³ or more, such as about 3.0 g/cm³ or more. The material density may be about 3.1 g/cm³ or less, such as about 3.0 g/cm³ or less, such as about 2.9 g/cm³ or less, such as about 2.8 g/cm³ or less, such as about 2.7 g/cm³ or less, such as about 2.6 g/cm³ or less, such as about 2.5 g/cm³ or less.

When the source material is a graphite converted structure, it may contain some unconverted graphite in addition to the silicon carbide. Similarly, it may contain some unreacted silicon or free silicon.

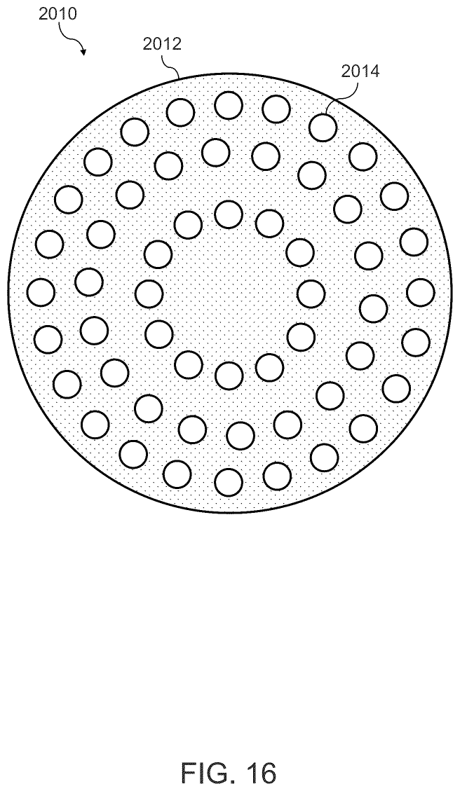

An example embodiment of a graphite converted source material structure is shown in FIG. 16. The composite structure 2010 contains a cylindrical base 2012 and channels 2014. The structure 2010 may be a graphite converted silicon carbide structure and the channels 2014 may be strategically placed to allow for good penetration of the silicon-containing gas into the graphite preform, even within the interior volume of the structure. The channels can be placed in a uniform manner to facilitate uniform graphite conversion as well as uniform sublimation properties. Alternatively, the channels may be placed in a non-uniform manner to facilitate non-uniform graphite conversion and non-uniform sublimation properties. When a graphite preform is used which has a needle coke structure, the thickness of the structure may be thicker and/or the placement of the channels 2014 may be further from each other compared to other types of graphite, since the needle coke structure may provide more efficient and deeper penetration of the silicon-containing gas.

In another embodiment, the silicon carbide source material structure may be a 3D printed silicon carbide structure. For example, in some embodiments, the source material is 3D printed from a 3D printing composition including SiC powder and a binder.

In some embodiments, the binder may form a non-graphitizable carbon under extreme heat, for example, at pyrolysis temperatures in a range of about 1600° C. to 3000° C. Examples of suitable binders include furan resin, furfuryl alcohol resin, UV curable polymer adhesives, and supramolecular organometallic curable fluids.

The UV curable polymer adhesives may comprise one or more photosensitive monomers or oligomers capable of being polymerized by UV light.

The UV curable polymer adhesive can be a commercial photopolymer or a photopolymer formulated by mixing monomers, oligomers, photoinitiators, and other additives such as photo-absorbers, dyes, and inhibitors. The monomer/oligomer can be (but is not restricted to) an acrylate-based monomer, an acrylamide-based monomer, a polyether, an acryloyl morpholine, a polyethylene glycol, an epoxy-based monomer, or a combination of these and other monomers.

Examples of acrylate-based monomers are acrylates (e.g., behenyl acrylate, or 2-hydroxyethyl acrylate), diacrylates (e.g., polyethylene glycol diacrylate), triacrylates (e.g., trimethylolpropane triacrylate), tetraacrylates (e.g., di(trimethylolpropane)tetraacrylate), and methacrylates (e.g., (hydroxyethyl)methacrylate).

An example of a polyether is polypropylene glycol.

Examples of acrylamide-based monomer are acrylamide, and N,N′-methylenebisacrylamide.

An example of an epoxy-based monomer is epoxy cyclohexane carboxylate.

In some embodiments, the UV-curable resin may comprise one or more photosensitive acrylate or methacrylate monomers or oligomers.

The photoinitiator can be (but is not restricted to) peroxides (e.g. benzoyl peroxide), nitrogen dioxide, camphorquinone, molecular oxygen, azobisisobutyronitrile, lithium phenyl-2,4,6-trimethylbenzoylphosphinate, benzoin methyl ether, 2,2-dimethoxy-2-phenylacetophenone, 2-hydroxy-2-methylphenylpropane-1-one, a-hydroxy-acetophenone, bis(2,6-dimethoxybenzoyl)-2,4,4-trimethylpentylphosphine oxide, 2-hydroxy-2-methyl-1-phenyl-propan-1-one, 2,4,6-trimethylbenzoyldiphenylphosphine oxide, or a combination of these and other photoinitiators.

Suitable photoinitiators may be selected from the group consisting of 2,2-dimethoxy-2-phenylacetophenone, 2-hydroxy-2-methylpropiophenone, camphorquinone, bis(2,4,6-trimethylbenzoyl)-phenylphosphineoxide, benzophenone, benzoyl peroxide, dicumyl peroxide, 2,2′-azobisisobutyronitrile, oxygen, nitrogen dioxide, and combinations or derivatives thereof. Other photoinitiators or thermal free-radical initiators may also be utilised.

In some embodiments, the photoinitiator is present from about 0.001 wt. % to about 15 wt. % of the UV-curable polymer. In various embodiments, the photoinitiator may be present in an amount from about 0.002 to about 10 wt. %, from about 0.01 to about 5 wt. %, or from about 0.1 to about 3 wt. % of the binder.

Depending on the 3D printing method used, the binder or a precursor thereof can be combined with the SiC powder prior to the 3D printing process or, alternatively, the binder can be added to the SiC powder during the printing process (e.g., a binder jet process). In some embodiments, the binder is combined with the SiC powder in the form of a similarly sized powder. In other embodiments, the binder is added to the SiC powder in liquid form and then cured into a solid during the 3D printing process.

The part can be 3D printed from a 3D printing composition as described above using known 3D printing techniques. Some examples of suitable 3D printing techniques are described below.

In some embodiments, the 3D printed part is produced through a powder bed 3D printing process. Powder bed fusion processes generally refer to processes where a powder is selectively sintered or melted and fused, layer-by-layer to produce a three-dimensional article. In one embodiment, the powder bed fusion process includes one or more lasers in a process known as laser sintering. During laser sintering, a laser is used to provide a pattern and heat to cause the binder particles to fuse or sinter together in a predetermined way. In addition to using one or more lasers as the heat source, powder bed fusion can also be achieved through the use of other forms of electromagnetic radiation, including, for example, infrared radiation, microwave energy, radiant heating lamps, and the like. The heat source can be coherent or incoherent. When using an incoherent heat source, a mask can be used in order to produce a three-dimensional article according to a particular pattern.

Three-dimensional articles formed through powder bed fusion include a plurality of overlying and adherent sintered or melted layers made from a 3D printing composition. For instance, the three-dimensional article can be made from more than about 8 layers, such as more than about 10 layers, such as more than about 15 layers, such as more than about 20 layers, such as more than about 25 layers, such as more than about 30 layers, such as more than about 40 layers, such as more than about 50 layers, and generally less than about 200,000 layers, such as less than about 150,000 layers. The number of layers can depend upon the particular application and the size of the final product.

In some embodiments, a powdered 3D printing composition is spread over a forming surface. A heat source, such as one or more laser beams, moves relative to the powder bed for producing a pattern in the particles. In one embodiment, the pattern is computer-controlled. In order to produce the pattern, the one or more lasers can move and scan over the forming surface, the forming surface can be moved relative to the lasers, or both the forming surface and the laser can be moved simultaneously. After one layer of powder has been sintered or melted together, another layer of powder is added to the forming surface and sintered or melted repeating the process. The process repeats as the one or more lasers melt and fuse each successive layer to the previous layer until a three-dimensional article is formed.

In some embodiments, the 3D printing composition of the present disclosure is used in a multi-jet fusion process. During multi-jet fusion, different components are combined with the powder during the printing process. For example, during a multi-jet fusion process, the powder is applied in patterns similar to the process described above. In addition to applying the powder, however, a fusing agent (e.g., one of the binders described above or a curing promoter for such a binder) can also be selectively applied to the particles that are to fuse together. In addition, optionally a detailing agent can be applied selectively where the fusing action of the particles needs to be reduced or amplified. For example, the detailing agent can be used to reduce fusing at the boundary to produce a part with sharp or smooth edges. During multi-jet fusion, the three components can be applied in sequence and repeatedly to build up layers and form a part or article.

During the three-dimensional printing process, various properties of the powder composition assist in producing a product having the desired characteristics. For example, the powder composition made up of the particles is preferably flowable. The powder composition should also be sinterable, meaning that the individual binder particles can bond together through thermal bonding or other suitable means. Consequently, formulating a 3D printing composition so as to have a larger operating window can facilitate particle-to-particle bonding and layer-to-layer bonding.

The powder composition, in one embodiment, can be incorporated into a printer cartridge that is readily adapted for incorporation into a three-dimensional printer system. The printer cartridge can include a dispensing container contained within a housing. The dispensing container can be for feeding the powder composition into the three-dimensional printer system.

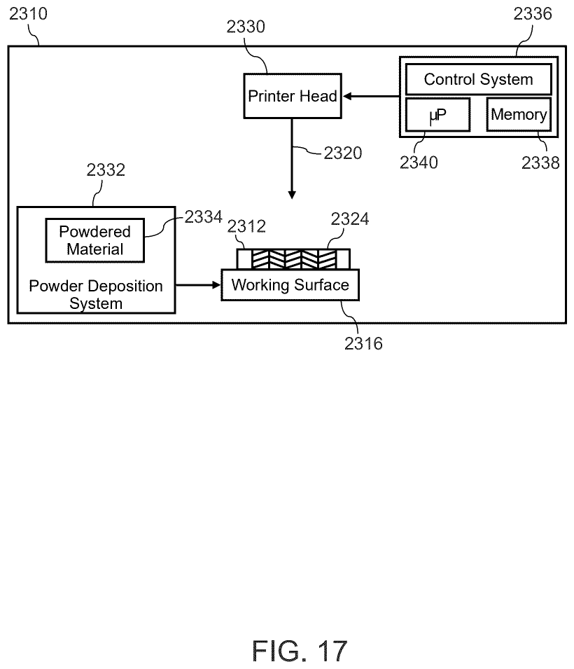

With reference to FIG. 17, an embodiment of a fusion bed printing system is shown. The printing system 2310 comprises a functional platform 2316 providing support for a layer of powder 2312. Additionally, the system 2310 incorporates a powder deposition system 2332 responsible for depositing a powder composition 2334, as disclosed herein, onto the working platform 2316 to create the layer of powder 2312.

The three-dimensional printing system 2310 includes a printer head 2330 emitting an energy source 2320 onto the powder 2312 and the working surface 2316. The printer head 2330 includes, for example, one or more lasers or alternative energy sources. For example, the energy source may also be a binder as described herein or a curing agent for a binder precursor that is already contained in the powdered material 2334.

Communication with a control system 2336 is established for governing the printer head's operation. The control system 2336, which may involve a distributed control system or a computer-based workstation, either fully or partially automated, encompasses memory circuitry 2338 storing instructions for controlling the printer head 2330. In some examples, the memory 2338 holds CAD designs dictating the formation of a three-dimensional article 2324 on the working surface 2316. Comprising one or more processing devices, such as a microprocessor 2340, the control system 2336 utilizes memory circuitry 2338 consisting of tangible, non-transitory, machine-readable media collectively storing instructions executable by the processing device 2340, facilitating the production of three-dimensional articles using the printer head 2330.

As depicted in FIG. 17, during the printing process, the powder 2312 can undergo heating to achieve a molten state to fuse the binder with the ceramic powder. Alternatively, the binder can be selectively cured by a chemical agent to fuse the binder and the ceramic powder particles together. The individual particles undergo fusion, sintering, or bonding with the binder, and the three-dimensional article 2324 is formed in a layer-by-layer fashion, with each successive layer thermally or chemically bonding together.

As previously described, in some embodiments, the powder 2312 is deposited onto the working platform 2316. The layer of particles is then combined with a binder selectively applied in a specific pattern. Optionally, a detailing agent may also be applied to the particles following a prescribed pattern. Subsequently, energy is applied to facilitate the formation of a layer of the article.

Various other three-dimensional printing techniques, such as extrusion-based systems (e.g., fused deposition modeling) and electrophotography, may be employed. For instance, in a fused deposition modeling system, the 3D printing composition may function as a build material forming the three-dimensional structure and/or a support material removed from the structure post-formation.

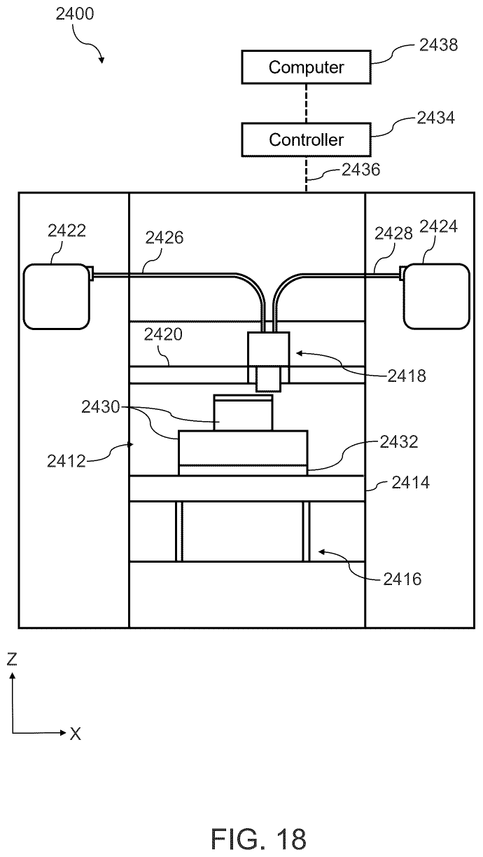

Referring to FIG. 18, an embodiment of an extrusion-based three-dimensional printer system 2400 is illustrated. This system selectively forms a precursor object containing a three-dimensional build structure 2430 and a corresponding support structure 2432 within build chamber 2412. The 3D printing composition described herein may be employed to form the build structure 2430. Conventional materials may be employed for the support structure 2432.

The system 2400, including a controller 2434, is equipped with a nozzle 2418 for printing the build structure 2430 and support structure 2432 on a substrate 2414. The nozzle 2418 is attached to a head frame 2420 allowing it to move side-to-side and front-to-back (i.e., in the X and Y directions). The nozzle 2418 is connected to a build material reservoir 2422 via a build material supply line 2426 and a support material reservoir 2424 via a support material supply line 2428. The controller 2434 communicates with the printing components via communication line 2436 to monitor and operate the system components and may communicate with a computer 2438 to transmit instructions for the selective formation of three-dimensional structures.

The build structure 2430 is constructed layer-by-layer. In this regard, the build structure 2430 is built on a build platform 2414 which is moved vertically via support structures 2416 (i.e., in the Z direction).

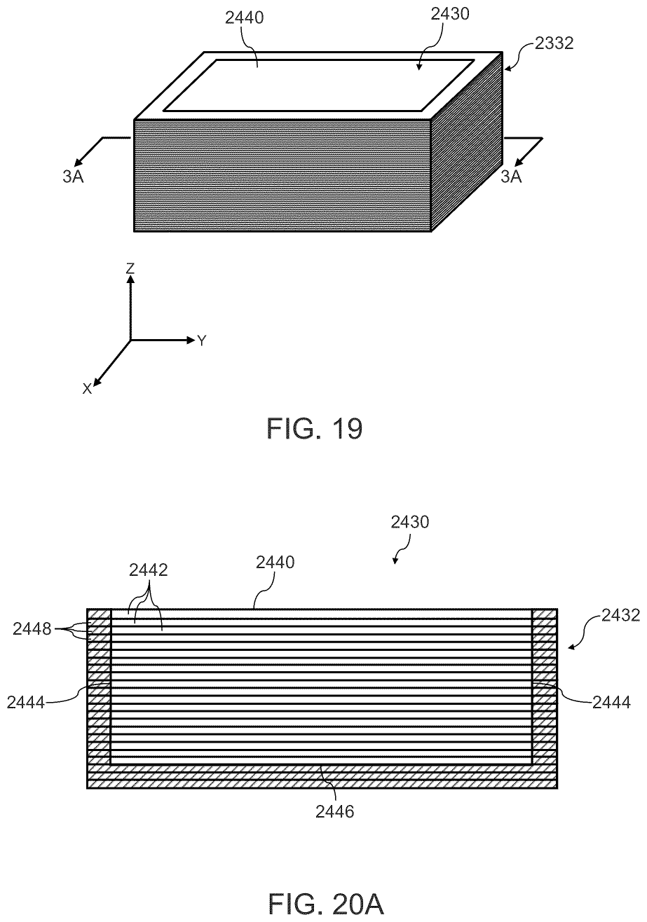

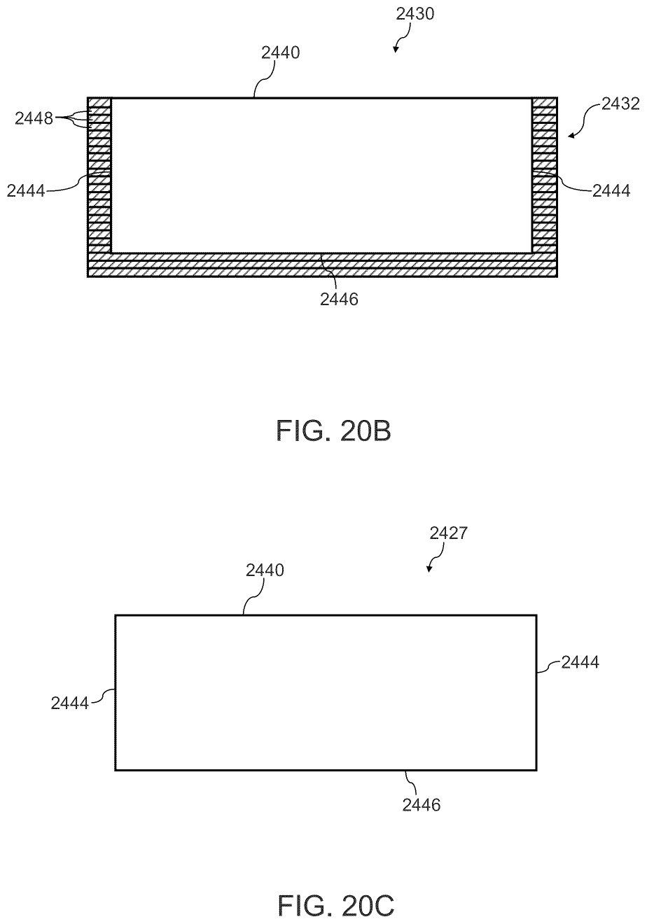

As shown in FIG. 19, the build structure 2430 is printed onto the substrate 2414 in successive layers of the build material, while the support structure 2432 is concurrently printed in successive layers, coordinating with the build structure 2430. The illustrated embodiment presents the build structure 2430 as a simple block-shaped object, featuring a top surface 2440, four lateral surfaces 2444 (FIG. 20A), and a bottom surface 2446 (FIG. 20A). While not obligatory, the support structure 2432 in this embodiment is deposited to partially encapsulate the layers of the build structure 2430. For instance, the support structure 2432 may be printed to encapsulate the lateral surfaces and the bottom surface of the build structure 2430. It should be noted that the system 2410 may print three-dimensional objects with various geometries in alternative embodiments. In such cases, the system 2410 may also print corresponding support structures, optionally partially encapsulating the three-dimensional objects.

FIGS. 20A-20C provide insight into the process of printing the three-dimensional build structure 2424 and support structure 2432 as described above. As depicted in FIG. 20A, each layer of the build structure 2430 is printed in a series of layers 2442 to define the geometry of the build structure 2430. In this particular embodiment, each layer of the support structure 2432 is printed in a series of layers 2448, coordinating with the printing of layers 2442 of the three-dimensional build structure 2430. The printed layers 2448 of the support structure 2432 encapsulate the lateral surfaces 2444 and the bottom surface 2446 of the build structure 2430, while the top surface 2440 remains unencapsulated by the layers 2448 of the support structure 2432. Upon completion of the print operation, the support structure 2432 can be removed from the build structure 2430, resulting in the creation of a three-dimensional object 2427. For instance, in embodiments where the support material is at least partially soluble in water or an aqueous alkaline solution, the resulting object may undergo immersion in a water and/or aqueous alkaline solution bath to dissolve the support structure 2432.

The use of 3D printing methods, including those described above, allows for the production of complex structures that could not be produced, or would be very difficult to produce by conventional methods.

Following 3D printing using any suitable method, including those described above, the resulting green component can undergo sintering, for example, by heating to a temperature of about 1500° C. or more.

In some embodiments, instead of 3D printing silicon carbide directly, a graphite precursor can be 3D printed and then converted to silicon carbide by the CVR process mentioned above. In such embodiments, the 3D printing composition can contain graphite particles instead of silicon carbide particles.

In some embodiments, one or more components of the grower may also be 3D printed. For example, at least a portion of the crucible 114, seed holder 124, source material holder 130, inlet 220, foamed structure 350, or insulation material 118 can be 3D printed. When such components are 3D printed, they may be formed from graphite or a ceramic material which may or may not contain SiC. When a source retention mechanism is contained, it may also be 3D printed, for example, from SiC and used as a secondary source material or from graphite or another ceramic material.

In some embodiments, a base silicon carbide structure is formed, for example, by any of the methods described above and then machined to produce the final source material structure. For example, in some embodiments, a silicon carbide base structure (e.g., a cylindrical structure) may be formed and then one or more holes, channels, slots, or the like may be drilled or otherwise machined from the base structure.

As explained above, in layered embodiments, the layers may be formed by the same or different methods. For example, in some embodiments, both layers may be 3D printed. In such embodiments, different 3D printing compositions may be used for each layer. In other embodiments, such as when both layers are flat and stacked or when one layer only partially surrounds the other, the layers may be formed separately by any suitable method and then joined together to form the source material structure. The two separate layers may or may not be adhered to each other. In some embodiments, for example, they may be only be physically stacked or mechanically linked, such as when one layer forms a cap-like structure over the other (e.g., FIGS. 8A-8C). Alternatively, they may be bonded together using a binder or adhesive. In other embodiments, particularly when the structure contains a core inner layer and a surrounding outer layer, the inner layer may be formed by any suitable method and the outer layer may be formed by a casting or molding process using a mold that fits around the inner layer with a gap for molding the outer layer. In another embodiment, the outer layer may be coated onto the inner layer, for example, by binding a composition containing SiC particles to the surface of the inner layer using a binder or adhesive. In other embodiments, an outer layer may be formed around an inner layer by surrounding the inner layer with SiC particles and sintering the particles to form the outer layer. It should be understood that the above methods are simply examples of methods for forming the layers and any suitable process may be used.

Regardless of the formation method, the resulting source material structure may have properties which enhance the sublimation process. For example, the shaped solid structure may have a material density (i.e., skeletal density) from 1.0 g/cm³ to about 3.21 g/cm³, such as from about 1.4 g/cm³ to about 3.2 g/cm³, such as from about 2.0 g/cm³ to about 3.2 g/cm³, such as from about 2.5 g/cm³ to about 3.0 g/cm³. The apparent density of the source material structure may be from about 1.0 g/cm³ to about 3.21 g/cm³. The shaped solid structure may have a total porosity of about 5% or greater, such as about 10% or greater, such as about 20% or greater, such as about 30% or greater, such as about 40% or greater, such as about 50% or greater, such as about 60% or greater, such as about 70% or greater, and about 90% or less, such as about 80% or less, such as about 70% or less, such as about 60% or less, such as about 50% or less, such as about 40% or less. The shaped solid structure may have a ratio of open porosity to total porosity of 0.5 or more, such as about 0.6 or more, such as about 0.7 or more, such as about 0.8 or more, such as about 0.9 or more. The combination of grain size, total porosity, open porosity, and density may be selectively controlled such that the solid source material exhibits high sublimation activation. The total volume of the source material may be determined based on the density of the source material and the desired total volume of the crystal that will be grown.

As described above, the solid source material, including source retention mechanisms such as those shown in FIGS. 23A and 23B, may have portions with varying properties. For example, a solid source material may contain one portion with a first porosity and another portion with a second porosity different from the first porosity. For example, the second porosity may differ by about 1% or more, such as 2% or more, such as 3% or more, such as 5% or more, such as 7% or more, such as 10% or more, such as 15% or more, such as 20% or more, such as 25% or more such as 30% or more, such as 40% or more, such as 50% or more from the first porosity. Such porosities may refer to total porosity or percentage of open porosity. As described above, other properties, such as density and grain size may similarly vary in different portions of the solid source material.

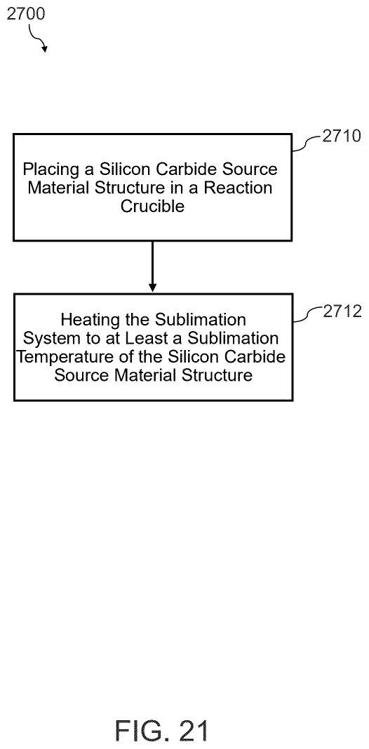

FIG. 21 depicts a flow chart diagram of an example method 2700 according to example embodiments of the present disclosure. FIG. 21 depicts example method steps for purposes of illustration and discussion. Those of ordinary skill in the art, using the disclosures provided herein, will understand that the methods described in the present disclosure may be adapted, modified, include steps not illustrated, omitted, and/or rearranged without deviating from the scope of the present disclosure.

In general method 2700 is a method for growing a single-crystal of silicon carbide (SiC crystal) using a physical vapor transport (PVT) process in a sublimation system. At (2702), method 2700 may include placing a source material containing silicon carbide in a reaction crucible. The source material comprises the source material structure described herein.

At (2704), method 2700 may comprise heating the sublimation system to at least a sublimation temperature of the silicon carbide source material structure. For example, a typical SiC sublimation process is described as follows. However, those familiar with the growth of crystals, particularly in difficult material systems such as silicon carbide, will recognize that the details of the given technique can vary depending on relevant circumstances.

Typically, growth pressure during an applied PVT process will range from about 0.1 to 400 Torr, and more typically between 0.1 and 100 Torr. The process temperature will range from about 2000° C. to about 3000° C. and in some embodiments, from about 2000° C. to about 2500° C. These conditions may vary due to differences in the sublimation system being used and variations in the seeded sublimation growth process being run. The thermal gradient between the growing crystal and the source material is typically controlled in a range of about 50 to 150° C./cm. A sublimating SiC species flux during the process period may be controlled by a ramped increase in the growth temperature in the range of 0.3 to 10° C./hr.

The sublimation process may include the steps of first evacuating the environment around the reaction crucible to remove ambient air, gaseous impurities and extraneous solid particulates. Then, the reaction crucible may be placed under pressure using one or more inert gas(es). Then, the sublimation system may heat the reaction crucible environment to a temperature enabling SiC crystal growth via PVT. Once this temperature is reached, the pressure within the sublimation system may be reduced to a point sufficient to initiate SiC crystal growth. In some embodiments, one or more carrier gasses (e.g., H₂, CH₄, Cl) may be used to increase growth rate or control the ratio of Si to C in the vapor.

In certain embodiments of the invention, one or more type of dopant atoms may be intentionally introduced into sublimation system during or before the seeded sublimation process. For example, one or more dopant gases may be introduced into the seeded sublimation environment and thereby incorporated into the growing SiC crystalline boule. Dopants may be selected for their acceptor or donor capabilities in accordance with the conductivity properties desired for the resulting SiC boule. For certain semiconductor devices, donor dopants produce n-type conductivity and acceptor dopants produce p-type conductivity. Some commonly incorporated n-type dopants include N, P, As, Sb, and/or Ti. Some commonly incorporated p-type dopants include B, Al, Ga, Be, Er, and/or Sc.

With reference again to FIG. 1, in a typical sublimation growth process according to an embodiment of the invention, an electrical current having a defined frequency to which the material (e.g., carbon) forming reaction crucible 114 will respond is passed through induction coils 116 to heat reaction crucible 114. The amount and placement of insulation material 118 are selected to create a thermal gradient between a source material 120 and a seed material 122. Reaction crucible 114 is heated with source material 120 to a sublimation temperature (e.g., above about 2000° C.). In this manner, a thermal gradient is established such that the temperature of seed material 122 and the SiC crystalline boule growing on the seed material 122 remains slightly below the temperature of source material 120. In this manner, certain vaporized species generated from the sublimating SiC source (e.g., Si, Si₂C and/or SiC₂) are thermodynamically transported first to seed material 122 and thereafter to the growing SiC crystalline boule (or “the SiC crystal”). The SiC crystal may have a 4H crystal structure, 6H crystal structure, 3C crystal structure, or other crystal structure, depending on the seed material used.

Once the SiC crystal has reached a desired size, the crystal growth process may be terminated by reducing the temperature of sublimation system 112 below about 1900° C. and/or raising the pressure of the environment surrounding reaction crucible 114 above about 400 Torr.

Wafers cut from such SiC crystals may be subsequently used in the fabrication of various substrates. For example, using known techniques, high quality semiconductor wafers may be fabricated that include homo-epitaxial layers, such as SiC, as well as hetero-epitaxial layers, such as Group III-nitrides, on at least one surface thereof. The Group III-nitride layer may be, for example, GaN, AlGaN, AlN, AlInGaN, InN, and/or AlInN.

The SiC substrate will include at least one and possibly two primary (and opposing) surfaces. As is conventionally understood, a plurality of active and/or passive devices may be fabricated on the SiC substrate.

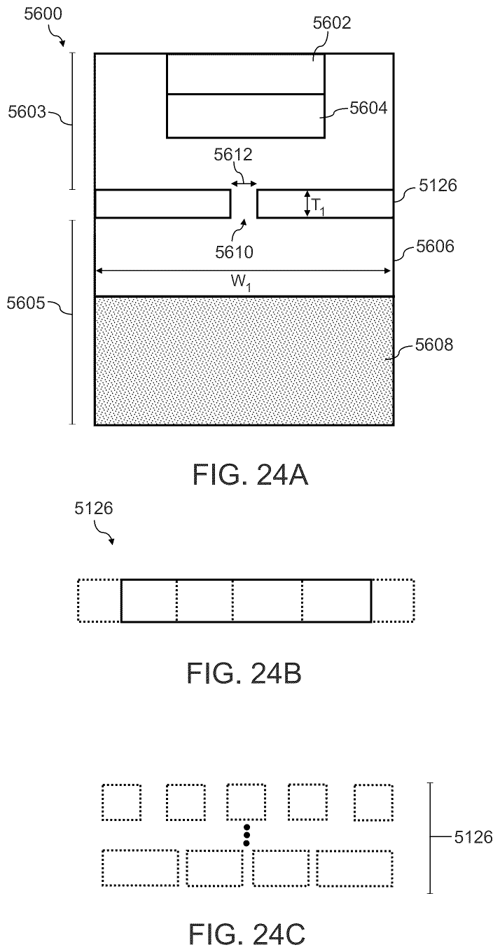

FIGS. 24A-31 depict example crystal growth systems that include a baffle according to example embodiments of the present disclosure. Any of the source material of the crystal growth systems of FIGS. 24A-31 may include a source material according to example embodiments of the present disclosure.

FIG. 24A depicts a simplified view of a crystal growth system 5600 according to example aspects of the present disclosure. The crystal growth system 5600 includes the seed holder 5602 configured to hold the seed crystal 5604. The seed crystal 5604 may provide a growth surface for growth of the silicon carbide crystalline material in a crystal growth process. The crystal growth system 5600 includes the crucible 5606 defining a crystal growth chamber. The crystal growth system 5600 includes the source material 5608. The crystal growth system 5600 includes a baffle 5126 within the crystal growth chamber that is spaced apart from the source material 5608. In some embodiments, the baffle 5126 may extend between the inner walls of the crucible 5606, such that the crucible 5606 is bisected or divided into an upper portion 5603 and a lower portion 5605 by the baffle 5126. The upper portion 5603 and the lower portion 5605 may have the same or different volumes. In some examples, the baffle 5126 may be coupled to a side wall of the crucible 5606. In some examples, the baffle 5126 may not fully extend between the inner walls of the crucible 5606.

The baffle 5126 has a long dimension (e.g., width) W1 and a thickness T1. The thickness T1 is in a general direction of vapor transport through the baffle 5126. In some embodiments, the long dimension W1 is in a direction that is non-perpendicular to the growth surface of the seed crystal 5604.

FIG. 24B depicts a simplified view of baffle 5126 according to some aspects of the present disclosure. As shown in FIG. 24B, baffle 5126 may include apertures, and may extend to the side walls of the crucible, or may not extend to the sidewalls of the crucible.

FIG. 24C depicts a simplified view of baffle 5126 according to some aspects of the present disclosure. As shown in FIG. 24C, baffle 5126 may include multiple baffle structures, which may be spaced apart from one another or may be in contact with one another.

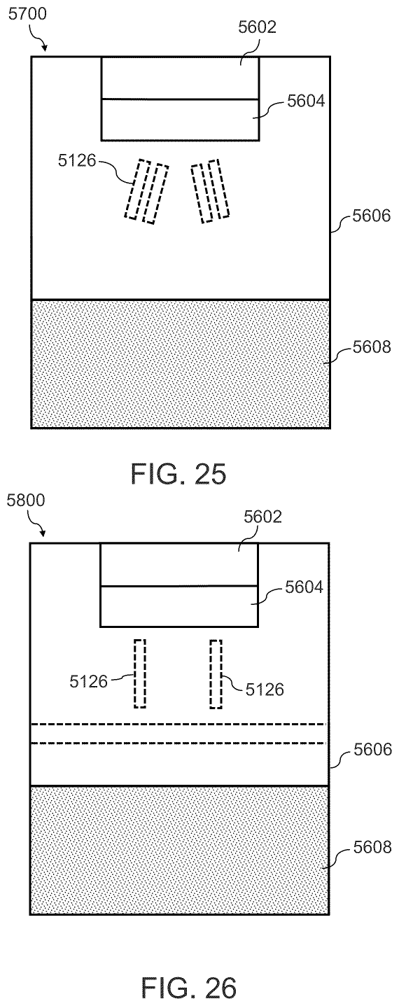

FIGS. 25, 26, 27, 28, 29, 30, and 31 depict simplified views of a baffle 5126 according to some aspects of the present disclosure in the context of crystal growth systems 5700, 5800, 5900, 6000, 6050, 6100, and 6200. As shown in FIG. 25, in some embodiments of the present disclosure, baffle 5126 may include one or more baffle plates, in any orientation relative to the seed holder 5602 or the source material 5608. As shown in FIG. 26, in some embodiments of the present disclosure, the baffle 5126 may include two or more baffle structures, whether of the same type or of differing types, and such baffle structures may be of differing orientations relative to each other.

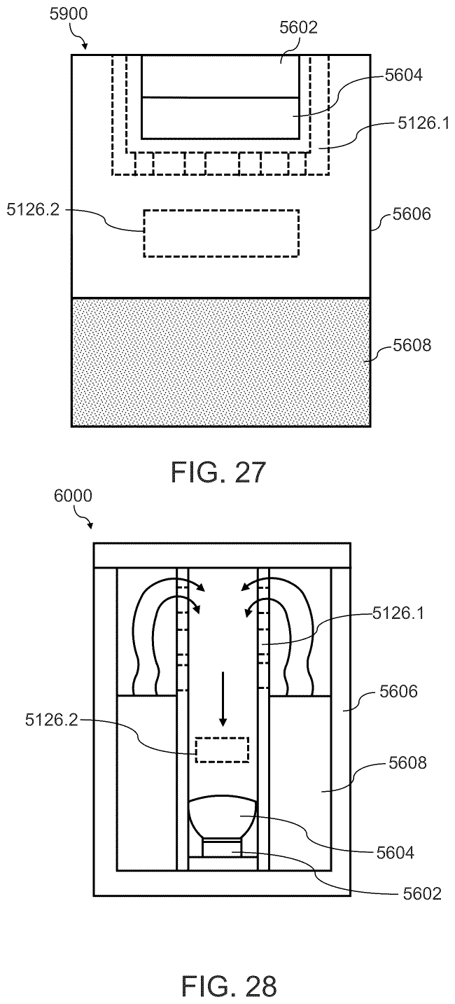

FIG. 27 depicts an example crystal growth system 5900 according to example embodiments of the present disclosure. In FIG. 27, the crystal growth system 5900 includes the baffle 5126.1, the seed holder 5602, the seed crystal 5604, the crucible 5606, and the source material 5608. The baffle 5126.1 may or may not include any apertures. The baffle 5126.1 may be porous graphite and may have a porosity of greater than about 70%. The baffle 5126 may be positioned such that the baffle 5126.1 extends around at least three sides of the seed crystal 5604, with the longest dimension located below the seed crystal 5604. The baffle 5126.1 may be referred to as a shell structure as it provides a shell around the seed crystal 5604. The baffle 5126 may be graphite, such as porous graphite. The baffle 5126.1 may include one or more apertures 5610 that assist in the transport of source vapor from the source material 5608 to the seed crystal 5604. The system 5900 may further include one or more second baffles 5126.2. The one or more second baffles 5126.2 may be arranged in the vapor transport path between the source material 5608 and the seed crystal 5604. The one or more second baffles 5126.2 may include any of the baffles disclosed in U.S. patent application Ser. No. 18/962,454 filed on Nov. 27, 2024, which is incorporated herein by reference.

FIG. 28 depicts an example crystal growth system 6000 according to example embodiments of the present disclosure. In FIG. 28, the crystal growth system 6000 includes a baffle 5126.1, a seed holder 5602, a seed crystal 5604, a crucible 5606, and the source material 5608. The baffle 5126.1 may include a tubular baffle structure. The baffle 5126.1 may or may not include apertures. The seed crystal 5604 may be within the tubular baffle 5126.1. The baffle 5126.1 may be graphite, such as porous graphite. The baffle 5126.1 may be porous graphite and may have a porosity of greater than about 70%. The baffle 5126.1 may include one or more apertures 5610 that assist in the transport of source vapor from the source material 5608 to the seed crystal 5604. The system 6000 may further include one or more second baffles 5126.2. The one or more second baffles 126.2 may be arranged in the vapor transport path between the source material 5608 and the seed crystal 5604. The one or more second baffles 5126.2 may include any of the baffles disclosed in U.S. patent application Ser. No. 18/962,454 filed on Nov. 27, 2024, which is incorporated herein by reference. The baffle 5126.1 and/or the baffle 5126.2 may serve to reduce graphite inclusions or other impurities resulting from gravitational forces pulling impurities toward the seed crystal 5604.

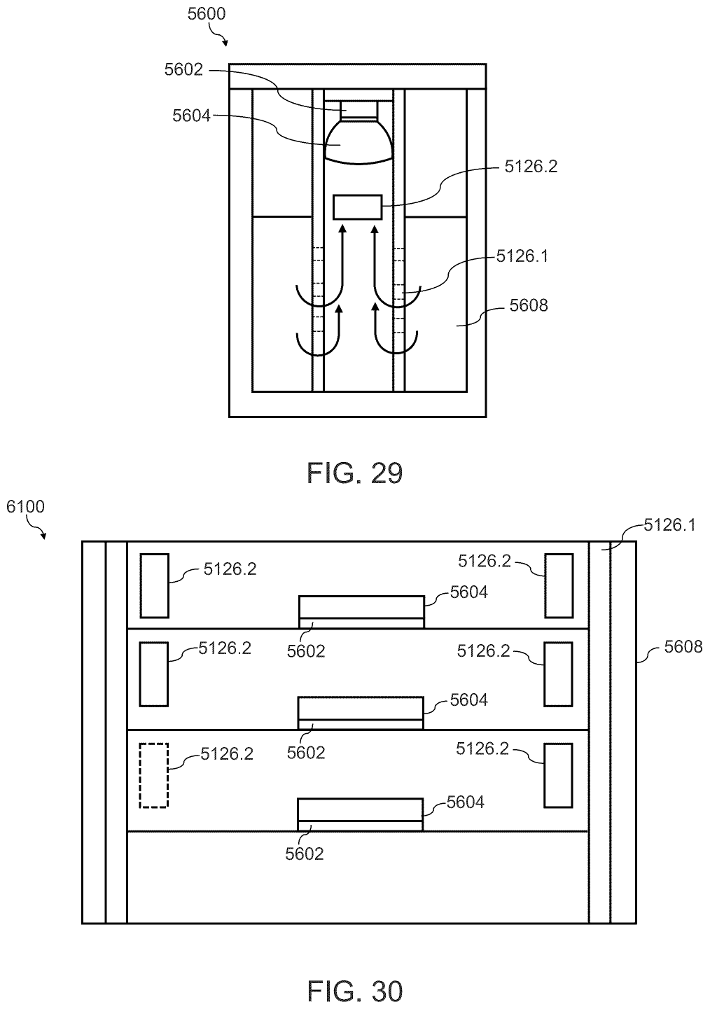

In FIG. 29, the crystal growth system 6050 includes the seed crystal 5604 at the top of the crucible 5606. Similar to FIG. 28, the baffle 5126.1 may include a tubular baffle structure. The seed crystal 5604 may be within the tubular baffle 5126.1. The baffle 5126.1 may be graphite, such as porous graphite. The baffle 5126.1 may be porous graphite and may have a porosity of greater than about 70%. The baffle 5126.1 may include one or more apertures 5610 that assist in the transport of source vapor from the source material 5608 to the seed crystal 5604. The system 6000 may further include one or more second baffles 5126.2. The one or more second baffles 5126.2 may be arranged in the vapor transport path between the source material 5608 and the seed crystal 5604. The one or more second baffles 5126.2 may include any of the baffles disclosed in U.S. patent application Ser. No. 18/962,454 filed on Nov. 27, 2024, which is incorporated herein by reference.

FIG. 30 depicts an example crystal growth system 6100 that may be used to grow a plurality of silicon carbide boules according to example embodiments of the present disclosure. In FIG. 30, the crystal growth system 6100 includes a plurality of seed holders 5602 and seed crystals 5604 arranged in different crystal growth chambers. A baffle 5126.1 may separate the seed crystals 5604 from a source material 5608. The baffle 5126.1 may include one or more apertures to assist with vapor transport from the source material 5608 to the seed crystals 5604. The system 6100 may further include one or more second baffles 5126.2. The one or more second baffles 5126.2 may be arranged in the vapor transport path between the source material 5608 and the seed crystal 5604. The one or more second baffles 5126.2 may include any of the baffles disclosed in U.S. patent application Ser. No. 18/962,454 filed on Nov. 27, 2024, which is incorporated herein by reference.

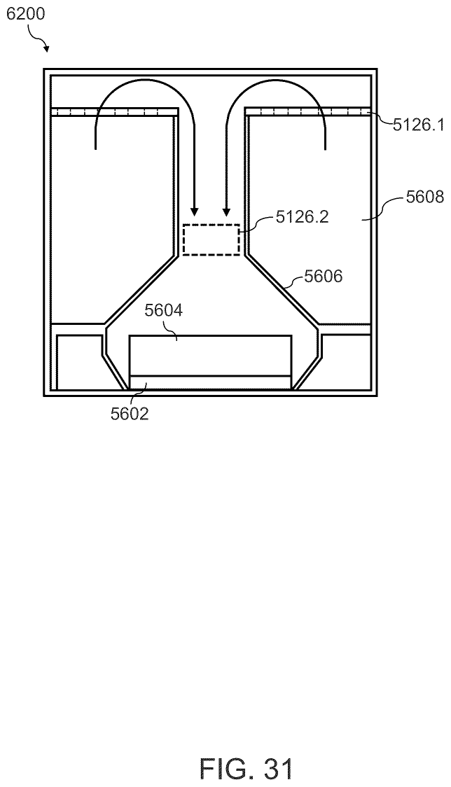

FIG. 31 depicts an example crystal growth system 6200 according to example embodiments of the present disclosure. In FIG. 31, the crystal growth system 6200 includes a seed holder 5602 and a seed crystal 5604 arranged within a crucible 5606. The crucible 5606 may have one or more angled sidewalls. The crystal growth system 6200 includes a source material 5608. The baffle 5126.1 may be on top of the source material 5608 and may separate the source material 5608 from the reaction chamber defined by the crucible 5606. As depicted in FIG. 23, the baffle 5126.1 may include one or more apertures to assist with vapor transport from the source material 5608 to the seed crystal 5604. The system 6100 may further include one or more second baffles 5126.2. The one or more second baffles 5126.2 may be arranged in the vapor transport path between the source material 5608 and the seed crystal 5604. The one or more second baffles 5126.2 may include any of the baffles disclosed in U.S. patent application Ser. No. 18/962,454 filed on Nov. 27, 2024, which is incorporated herein by reference.

In any of the simplified crystal growth systems with a baffle 5126.1, 5126.2 depicted in FIGS. 24A-31 or baffle 126 of FIGS. 1-3, the baffle may provide vapor transport of a silicon carbide source vapor through a first portion of the baffle at a first rate. In some embodiments, the silicon carbide vapor may be transported through a second portion of the baffle (e.g., including one or more apertures), at a second rate. The first rate may be different than the second rate. For example, the baffle may provide an avenue for source vapor to diffuse through the material of the baffle at a first rate, while source vapor is transported through an aperture unimpeded by the material of the baffle at a second rate.

In some embodiments, the baffle may be spaced apart from the seed holder and is not coupled to the seed holder. In some embodiments, the baffle may impede or otherwise alter heat transfer or thermal energy within the crystal growth chamber in a crystal growth process.

In some embodiments, the baffle may be, at least partially, made of graphite. In some embodiments, the baffle made at least partially of graphite may include a coating on at least a portion of the graphite. In some embodiments, the coating on the baffle made of graphite may be a pyrolytic coating. In some embodiments, the coating on the baffle made of graphite may be tantalum carbide. In some embodiments, the coating on the baffle may hinder particulate matter larger than the source vapor from reaching a seed crystal. The seed crystal may be a silicon carbide seed crystal. Example coatings that may be used are disclosed in U.S. Provisional Application Ser. No. 63/700,682, filed on Sep. 28, 2024, U.S. Provisional Application Ser. No. 63/700,685, filed on Sep. 28, 2024 and U.S. Provisional Application Ser. No. 63/700,686, filed on Sep. 28, 2024, which are incorporated herein by reference. The baffle may have undergone various treatments (e.g., may be a treated graphite structure) to reduce carbon inclusions in the baffle. Example treated graphite structures are disclosed in U.S. Provision Application Ser. No. 63/700,630, filed on Sep. 28, 2024 which is incorporated herein by reference.

In some examples, the graphite is porous graphite. For instance, the baffle may have a porosity in a range of about 50% to about 97%, such as about 75% to about 97%, such as about 80% to about 97%. Other suitable materials may be used without deviating from the scope of the present disclosure. For instance, the baffle may comprise a carbide material, such as vanadium carbide, tantalum carbide, silicon carbide. The carbide material may form a bulk of the baffle.

In some examples, at least a portion of the baffle includes uncoated graphite or exposed graphite. For instance, at least a portion of a surface of the baffle facing the seed crystal may be exposed or uncoated graphite. This will allow that baffle to serve as a secondary source to improve crystal growth during a PVT crystal growth process.

The seed crystal may be a silicon carbide seed crystal. In some embodiments, the baffle may be spaced apart from a seed holder and is not coupled to the seed holder. In some embodiments, the baffle may be spaced apart from a source material and is not coupled to the source material. The source material may be a silicon carbide vapor source material. In some embodiments, the baffle may be coupled to a side wall of a crucible. In some embodiments, the baffle, or an individual baffle plate in embodiments including a plurality of baffle plates or baffle structures, may have a thickness that is in a range of about 0.5 mm to about 25 mm, such as 2 mm to about 12 mm, such as about 2 mm to about 8 mm.

In some embodiments, the baffle can include single or multiple elements that perform one of more of the following: effecting/providing temperature gradient in a desired manner relative to the crystal growth surface, effecting/providing vapor pressure/flux/flow for/to/from the source material (e.g., silicon carbon source material, secondary source material, or dopant source relative to the crystal growth surface, side surface of the seed crystal and/or areas within the reactor susceptible to parasitic growth; and filtering graphite or other inclusions from the crystal. In some embodiments, different elements or portions of the baffle can provide different features, such as one element for filtering, another element acting as a secondary source (e.g., a graphite element that provides a carbon source and provides temperature gradient and vapor pressure/flux effects); and an element with apertures, pores, voids, cavities, indentations and/or protrusions to effect temperature gradient and/or vapor flow/pressure effects. One or more of the baffles 126 can be coated with a high temperature carbide, such as TaC or the like) while others are not. Portions or the entire baffle can be coated or not with a single, multiple and/or patterned coating(s), for instance, to achieve desired sublimation if acting as a secondary source, or to reduce sublimation if not intended to serve as a secondary source. Individual baffles or baffle elements can serve duplicate or different functions.

Example aspects of the present disclosure are set forth below. Any of the below features or examples may be used in combination with any of the embodiments or features provided in the present disclosure.

In an aspect, the present disclosure provides an example silicon carbide source material structure. In some implementations, the example silicon carbide source material structure includes a first layer and a second layer, the first layer being different from the second layer in at least one property.

In some implementations of the example silicon carbide source material structure, the property is silicon carbide polytype.

In some implementations of the example silicon carbide source material structure, the first layer includes 3C SiC and the second layer includes 15R SiC.

In some implementations of the example silicon carbide source material structure, the first layer includes 3C SiC and the second layer includes 4H SiC.

In some implementations of the example silicon carbide source material structure, the first layer includes 3C SiC and the second layer includes 6H SiC.

In some implementations of the example silicon carbide source material structure, the first layer includes 3C SiC and the second layer includes 21R SiC.

In some implementations of the example silicon carbide source material structure, the first layer includes 15R SiC and the second layer includes 4H SiC.

In some implementations of the example silicon carbide source material structure, the first layer includes 15R SiC and the second layer includes 6H SiC.

In some implementations of the example silicon carbide source material structure, the first layer includes 15R SiC and the second layer includes 21R SiC.

In some implementations of the example silicon carbide source material structure, the first layer includes 4H SiC and the second layer includes 6H SiC.

In some implementations of the example silicon carbide source material structure, the first layer includes 4H SiC and the second layer includes 21R SiC.

In some implementations of the example silicon carbide source material structure, the first layer includes 6H SiC and the second layer includes 21R SiC.

In some implementations of the example silicon carbide source material structure, the property is material density of the silicon carbide.

In some implementations of the example silicon carbide source material structure, the first layer includes sintered or bound particles having a first average particle size and the second layer includes sintered or bound particles having a second average particle size different from the first average particle size.

In some implementations of the example silicon carbide source material structure, the first layer includes a silicon carbide powder and the second layer includes a solid structure.

In some implementations of the example silicon carbide source material structure, a ratio of the material density of the second layer to the material density of the first layer is about 1.2 or more.

In some implementations of the example silicon carbide source material structure, the first layer includes graphite converted silicon carbide and the second layer includes sintered or bound silicon carbide.

In some implementations of the example silicon carbide source material structure, the property is the composition of the layer.

In some implementations of the example silicon carbide source material structure, the first layer includes silicon carbide and a dopant and the second layer does not contain a dopant.

In some implementations of the example silicon carbide source material structure, the dopant includes vanadium, aluminum, or boron.

In some implementations of the example silicon carbide source material structure, the first layer includes silicon carbide and a first dopant and the second layer includes silicon carbide and a second dopant different from the first dopant.

In some implementations of the example silicon carbide source material structure, the property is silicon carbide purity.

In some implementations of the example silicon carbide source material structure, the property is the concentration of an impurity.

In some implementations of the example silicon carbide source material structure, the impurity selected from vanadium, boron, aluminum, nitrogen, cerium, germanium, and combinations thereof.

In some implementations of the example silicon carbide source material structure, a ratio of the concentration of an impurity in the first layer to the concentration of the impurity in the second layer is about 1.5 or more.

In some implementations of the example silicon carbide source material structure, the first layer at least partially surrounds the second layer.

In some implementations of the example silicon carbide source material structure, the first layer is a coating on the second layer.

In some implementations of the example silicon carbide source material structure, the first layer is a shaped solid with a cavity and the second layer is a powder contained within the cavity.

In some implementations of the example silicon carbide source material structure, the property is sublimation rate at 2000° C.

In some implementations of the example silicon carbide source material structure, the first layer at least partially surrounds the first layer and has a slower sublimation rate than the second layer at 2000° C.

In some implementations of the example silicon carbide source material structure, the property is total porosity.

In some implementations of the example silicon carbide source material structure, a ratio of the total porosity of the second layer to the total porosity of the first layer is about 1.2 or greater.

In some implementations of the example silicon carbide source material structure, at least one of the first or second layers includes a 3D-printed structure.

In some implementations of the example silicon carbide source material structure, at least one of the first or second layers includes an extruded silicon carbide structure.

In some implementations of the example silicon carbide source material structure, at least one of the first or second layers includes a casted silicon carbide structure.

In some implementations of the example silicon carbide source material structure, at least one of the first or second layers includes a hot pressed silicon carbide structure.

In some implementations of the example silicon carbide source material structure, at least one of the first or second layers includes a sintered silicon carbide structure.

In some implementations of the example silicon carbide source material structure, at least one of the first or second layers includes a graphite converted solid silicon carbide structure.

In some implementations of the example silicon carbide source material structure, the graphite converted solid silicon carbide structure is converted from a graphite preform.

In some implementations of the example silicon carbide source material structure, the graphite preform includes a needle coke structure.

In some implementations of the example silicon carbide source material structure, the graphite preform has a material density in a range of 1.4 to 1.6 g/cc.

In some implementations of the example silicon carbide source material structure, the graphite preform has a ratio of open porosity to total porosity in a range of 0.9 to 1.

In some implementations of the example silicon carbide source material structure, the graphite preform has a grain size in a range of 1 micron to 20 microns.

In an aspect, the present disclosure provides an example silicon carbide crystal growth sublimation system containing a crucible and the silicon carbide source material structure.

In some implementations of the example silicon carbide crystal growth sublimation system, the system further includes a seed material.

In an aspect, the present disclosure provides an example method for growing a single crystal of silicon carbide. The method includes placing the silicon carbide source material structure in a reaction crucible and heating the sublimation system to at least a sublimation temperature of the silicon carbide source material structure.

In an aspect, the present disclosure provides an example silicon carbide source material structure for use in a sublimation system for growing single crystal silicon carbide. The silicon carbide source material structure includes silicon carbide and a dopant.

In some implementations of the example silicon carbide source material structure, the dopant includes vanadium.

In some implementations of the example silicon carbide source material structure, the dopant includes aluminum.

In some implementations of the example silicon carbide source material structure, the dopant includes boron.

In some implementations of the example silicon carbide source material structure, the source material structure further includes graphite.

In some implementations of the example silicon carbide source material structure, the dopant is coated onto the graphite.

In some implementations of the example silicon carbide source material structure, the source material structure further includes silicon.

In some implementations of the example silicon carbide source material structure, the dopant is uniformly dispersed within the silicon carbide source material structure.

In some implementations of the example silicon carbide source material structure, the silicon carbide source material structure includes a first layer including silicon carbide and a second layer including the dopant. The second layer at least partially surrounds the first layer.

In some implementations of the example silicon carbide source material structure, the silicon carbide source material structure includes a shaped solid.

In some implementations of the example silicon carbide source material structure, the shaped solid has a material density from about 1.4 g/cm³ to about 3.1 g/cm³.

In some implementations of the example silicon carbide source material structure, the shaped solid has a material density from about 2.0 g/cm³ to about 2.6 g/cm³.

In some implementations of the example silicon carbide source material structure, the shaped solid has a total porosity from about 50% to about 80%.

In some implementations of the example silicon carbide source material structure, the shaped solid has a ratio of open porosity to total porosity of from about 0.8 to about 1.

In some implementations of the example silicon carbide source material structure, the shaped solid includes at least one 3D-printed structure.

In some implementations of the example silicon carbide source material structure, the shaped solid includes at least one extruded silicon carbide structure.

In some implementations of the example silicon carbide source material structure, the shaped solid includes at least one casted silicon carbide structure.

In some implementations of the example silicon carbide source material structure, the shaped solid includes at least one hot pressed silicon carbide structure.

In some implementations of the example silicon carbide source material structure, the shaped solid includes at least one sintered silicon carbide structure.

In some implementations of the example silicon carbide source material structure, the shaped solid includes at least one graphite converted solid silicon carbide structure.

In some implementations of the example silicon carbide source material structure, the graphite converted solid silicon carbide structure is converted from a graphite preform.

In some implementations of the example silicon carbide source material structure, the graphite preform includes a needle coke structure.

In some implementations of the example silicon carbide source material structure, the graphite preform has a material density in a range of 1.4 to 1.6 g/cc.

In some implementations of the example silicon carbide source material structure, the graphite preform has a ratio of open porosity to total porosity in a range of 0.9 to 1.

In some implementations of the example silicon carbide source material structure, the graphite preform has a grain size in a range of 1 micron to 20 microns.

In an aspect, the present disclosure provides an example silicon carbide crystal growth sublimation system including a crucible and the silicon carbide source material structure.

In some implementations of the example silicon carbide crystal growth sublimation system, the system further includes a seed material.

In an aspect, the present disclosure provides an example method for growing a single crystal of silicon carbide. The method includes placing the silicon carbide source material structure in a reaction crucible and heating the sublimation system to at least a sublimation temperature of the silicon carbide source material structure.

In an aspect, the present disclosure provides an example silicon carbide crystal growth sublimation system. The system includes a crucible, a silicon carbide source material structure, and a silicon carbide seed material. The source material comprises silicon carbide having a different polytype from the silicon carbide of the seed material.

In some implementations of the example silicon carbide source material structure, the source material includes 3C SiC and the seed material includes 15R SiC.

In some implementations of the example silicon carbide source material structure, the source material includes 3C SiC and the seed material includes 4H SiC.

In some implementations of the example silicon carbide source material structure, the source material includes 3C SiC and the seed material includes 6H SiC.

In some implementations of the example silicon carbide source material structure, the source material includes 3C SiC and the seed material includes 21R SiC.

In some implementations of the example silicon carbide source material structure, the source material includes 15R SiC and the seed material includes 4H SiC.

In some implementations of the example silicon carbide source material structure, the source material includes 15R SiC and the seed material includes 6H SiC.

In some implementations of the example silicon carbide source material structure, the source material includes 15R SiC and the seed material includes 21R SiC.

In some implementations of the example silicon carbide source material structure, the source material includes 4H SiC and the seed material includes 6H SiC.

In some implementations of the example silicon carbide source material structure, the source material includes 4H SiC and the seed material includes 21R SiC.

In some implementations of the example silicon carbide source material structure, the source material includes 6H SiC and the seed material includes 21R SiC.

In some implementations of the example silicon carbide source material structure, the silicon carbide source material structure includes a shaped solid.

In some implementations of the example silicon carbide source material structure, the shaped solid has a material density from about 1.4 g/cm³ to about 3.1 g/cm³.

In some implementations of the example silicon carbide source material structure, the shaped solid has a material density from about 2.0 g/cm³ to about 2.6 g/cm³.

In some implementations of the example silicon carbide source material structure, the shaped solid has a total porosity from about 50% to about 80%.

In some implementations of the example silicon carbide source material structure, the shaped solid has a ratio of open porosity to total porosity of from about 0.8 to about 1.

In some implementations of the example silicon carbide source material structure, the shaped solid includes at least one 3D-printed structure.

In some implementations of the example silicon carbide source material structure, the shaped solid includes at least one extruded silicon carbide structure.

In some implementations of the example silicon carbide source material structure, the shaped solid includes at least one casted silicon carbide structure.

In some implementations of the example silicon carbide source material structure, the shaped solid includes at least one hot pressed silicon carbide structure.

In some implementations of the example silicon carbide source material structure, the shaped solid includes at least one sintered silicon carbide structure.

In some implementations of the example silicon carbide source material structure, the shaped solid includes at least one graphite converted solid silicon carbide structure.

In some implementations of the example silicon carbide source material structure, the graphite converted solid silicon carbide structure is converted from a graphite preform.

In some implementations of the example silicon carbide source material structure, the graphite preform includes a needle coke structure.

In some implementations of the example silicon carbide source material structure, the graphite preform has a material density in a range of 1.4 to 1.6 g/cc.

In some implementations of the example silicon carbide source material structure, the graphite preform has a ratio of open porosity to total porosity in a range of 0.9 to 1.

In some implementations of the example silicon carbide source material structure, the graphite preform has a grain size in a range of 1 micron to 20 microns.

In an aspect, the present disclosure provides an example silicon carbide crystal growth sublimation system including a crucible and the silicon carbide source material structure.

In some implementations of the example silicon carbide crystal growth sublimation system, the system further includes a seed material.

In an aspect, the present disclosure provides an example method for growing a single crystal of silicon carbide. The method includes placing the silicon carbide source material structure in a reaction crucible and heating the sublimation system to at least a sublimation temperature of the silicon carbide source material structure.

In an aspect, the present disclosure provides an example method for growing a single crystal of silicon carbide. The method includes forming a silicon carbide source material structure, placing the silicon carbide source material structure in a reaction crucible, and heating the sublimation system to at least a sublimation temperature of the silicon carbide source material structure. Forming the silicon carbide source material structure comprises reacting a graphite preform having a needle coke structure with SiO gas.

In some implementations of the example method, the graphite preform has a material density in a range of 1.4 to 1.6 g/cc.

In some implementations of the example method, the graphite preform has a ratio of open porosity to total porosity in a range of 0.9 to 1.

In some implementations of the example method, the graphite preform has a grain size in a range of 1 micron to 20 microns.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A silicon carbide source material structure for use in a sublimation system for growing single crystal silicon carbide, the silicon carbide source material structure comprising:
a first layer and a second layer, the first layer being different from the second layer in at least one property.

2. The silicon carbide source material structure of claim 1, wherein the property is silicon carbide polytype.

3. The silicon carbide source material structure of claim 2, wherein the first layer comprises 3C SiC and the second layer comprises 15R SiC.

4. The silicon carbide source material structure of claim 2, wherein the first layer comprises 3C SiC and the second layer comprises 4H SiC.

5. The silicon carbide source material structure of claim 2, wherein the first layer comprises 3C SiC and the second layer comprises 6H SiC.

6. The silicon carbide source material structure of claim 2, wherein the first layer comprises 3C SiC and the second layer comprises 21R SiC.

7. The silicon carbide source material structure of claim 2, wherein the first layer comprises 15R SiC and the second layer comprises 4H SiC.

8. The silicon carbide source material structure of claim 2, wherein the first layer comprises 15R SiC and the second layer comprises 6H SiC.

9. The silicon carbide source material structure of claim 2, wherein the first layer comprises 15R SiC and the second layer comprises 21R SiC.

10. The silicon carbide source material structure of claim 2, wherein the first layer comprises 4H SiC and the second layer comprises 6H SiC.

11. The silicon carbide source material structure of claim 2, wherein the first layer comprises 4H SiC and the second layer comprises 21R SiC.

12. The silicon carbide source material structure of claim 2, wherein the first layer comprises 6H SiC and the second layer comprises 21R SiC.

13. The silicon carbide source material structure of claim 1, wherein the property is material density of the silicon carbide.

14. The silicon carbide source material structure of claim 13, wherein the first layer comprises sintered or bound particles having a first average particle size and the second layer comprises sintered or bound particles having a second average particle size different from the first average particle size.

15. The silicon carbide source material structure of claim 13, wherein the first layer comprises a silicon carbide powder and the second layer comprises a solid structure.

16. The silicon carbide source material structure of claim 13, wherein a ratio of the material density of the second layer to the material density of the first layer is about 1.2 or more.

17. The silicon carbide source material structure of claim 13, wherein the first layer comprises graphite converted silicon carbide and the second layer comprises sintered or bound silicon carbide.

18. The silicon carbide source material structure of claim 1, wherein the property is the composition of the layer.

19. The silicon carbide source material structure of claim 18, wherein the first layer comprises silicon carbide and a dopant and the second layer does not contain a dopant.

20. The silicon carbide source material structure of claim 19, wherein the dopant comprises vanadium, aluminum, or boron.
